(19) United States
(12) Patent Application Publication
(10) Pub. No.: US 2024/0120709 A1
(43) Pub. Date: Apr. 11, 2024

(54) SURFACE EMITTING ELEMENT, METHOD FOR DETECTING OPTIC CHARACTERISTIC, AND METHOD FOR ADJUSTING OPTICAL CHARACTERISTIC

(71) Applicant: SONY GROUP CORPORATION, TOKYO (JP)

(72) Inventors: EIJI NAKAYAMA, TOKYO (JP); TATSUSHI HAMAGUCHI, TOKYO (JP); KENTARO HAYASHI, TOKYO (JP); RINTARO KODA, TOKYO (JP); HIDEKAZU KAWANISHI, TOKYO (JP)

(21) Appl. No.: 18/264,698

(22) PCT Filed: Jan. 19, 2022
(86) PCT No.: PCT/JP2022/001696

§ 371 Date: Aug. 8, 2023

(30) Foreign Application Priority Data
Feb. 19, 2021 (JP) 2021-025083

(51) Int. Cl. H01S 5/0683; H01S 5/042; H01S 5/06; H01S 5/068; H01S 5/183

(52) U.S. Cl. CPC H01S 5/0683; H01S 5/0425; H01S 5/0601; H01S 5/06808; H01S 5/183

(57) ABSTRACT

The present technology provides a surface emitting element capable of enabling highly accurate detection of an optical characteristic of an emitted light and/or enabling adjustment of the optical characteristic of the emitted light. The surface emitting element of the present technology provides a surface emitting element including a light emitting layer, a characteristic layer that is disposed on an optical path of light generated in the light emitting layer, exhibits an electrical characteristic due to light incidence, and/or has variability in an optical characteristic due to voltage application, and a plurality of electrodes provided on the characteristic layer.

### TECHNICAL FIELD

The technology according to the present disclosure (hereinafter also referred to as “the present technology”) relates to a surface emitting element, a method for detecting an optical characteristic, and a method for adjusting an optical characteristic.

### BACKGROUND ART

Conventionally, a surface emitting element including a light detecting element is known (see Patent Document 1, for example). For example, a light detecting element of a semiconductor light emitting device (surface emitting element) disclosed in Patent Document 1 has a light absorbing layer that absorbs a part of light from a light emitting layer and converts the absorbed light into an electric signal.

### CITATION LIST

### Patent Document

Patent Document 1: Japanese Patent Application Laid-Open No. 2011-233940

### SUMMARY OF THE INVENTION

### Problems to be Solved by the Invention

However, in the conventional surface emitting element, there is room for improvement in enabling highly accurate detection of an optical characteristic of an emitted light and/or enabling adjustment of the optical characteristic of the emitted light.

Therefore, a main object of the present technology is to provide a surface emitting element capable of enabling highly accurate detection of an optical characteristic of an emitted light and/or enabling adjustment of the optical characteristic of the emitted light.

### Solutions to Problems

The present technology provides a surface emitting element including
a light emitting layer,
a characteristic layer that is disposed on an optical path of light generated in the light emitting layer, exhibits an electrical characteristic due to light incidence, and/or has variability in an optical characteristic due to voltage application, and
a plurality of electrodes provided on the characteristic layer.

The light emitting layer and the characteristic layer may be stacked on each other.

The plurality of electrodes may be disposed apart from each other along the characteristic layer.

The surface emitting element may further include a first reflector and a second reflector disposed at positions sandwiching the light emitting layer, in which the characteristic layer may be disposed between one of the first reflector or the second reflector and the light emitting layer.

The electrical characteristic may include a characteristic in which the electrical resistance changes in accordance with a change in the amount of incident light.

The variability in the optical characteristic may include that a light absorption end is shifted to a short wavelength side or a long wavelength side by the voltage application.

The characteristic layer may absorb a part of the incident light.

The characteristic layer may include a transparent conductive film.

The electrical characteristic may include a photoelectric conversion characteristic.

The light emitting layer may have a light emitting region and a non-light emitting region that surrounds the light emitting region, and the plurality of electrodes may include at least one first electrode disposed at a position corresponding to a section on one side of both sides sandwiching the light emitting region in the non-light emitting region, the plurality of electrodes including at least one second electrode disposed at a position corresponding to a section on an another side of the both sides.

The characteristic layer may be disposed so as to overlap at least a position having the highest light emission intensity in an in-plane direction of the light emitting region.

In the characteristic layer, a size of a region corresponding to the light emitting region may be smaller in plan view than a size of a region corresponding to the non-light emitting region on each of the both sides sandwiching the light emitting region.

In the region corresponding to the light emitting region of the characteristic layer, a part corresponding to the position having the highest light emission intensity may have the smallest size in plan view.

The at least one first electrode may include a first electrode group including a plurality of first electrodes, and the at least one second electrode may include a second electrode group including a plurality of second electrodes corresponding to the plurality of the first electrodes, and a plurality of electrode pairs each including the plurality of first electrode electrodes and the plurality of second electrodes corresponding to each other may be disposed at positions corresponding to a plurality of different regions in the in-plane direction of the characteristic layer.

The plurality of regions may be integrated.

At least two of the plurality of regions may be separated from each other.

At least one of the plurality of electrodes may also serve as an electrode for supplying a current to the light emitting layer or an electrode for flowing out the current supplied to the light emitting layer.

The present technology also provides a method for detecting an optical characteristic of a light emitted from a surface emitting element including a light emitting layer, a characteristic layer that is disposed on an optical path of light generated in the light emitting layer and exhibits an electrical characteristic due to light incidence, and a plurality of electrodes including a first electrode and a second electrode provided on the characteristic layer, the method including
applying substantially the same potential to the first electrode and the second electrode to drive the surface emitting element,
generating a potential difference between the first electrode and the second electrode by superimposing a potential on at least one of the first electrode or the second electrode while the surface emitting element is being driven, and
measuring the electrical characteristic of the characteristic layer.

The present technology also provides a method for detecting an optical characteristic of a light emitted from a surface emitting element including a light emitting layer, a characteristic layer that is disposed on an optical path of light generated in the light emitting layer and exhibits an electrical characteristic due to light incidence, a plurality of electrodes including a first electrode and a second electrode provided on the characteristic layer, and a third electrode disposed on a side opposite to the characteristic layer of the light emitting layer, the method including
applying substantially the same potential to the first electrode and the second electrode to drive the surface emitting element,
turning off driving of the surface emitting element and applying substantially the same potential to one of the first electrode or the second electrode and the third electrode, and
measuring the electrical characteristic of the characteristic layer.

The present technology also provides a method for adjusting an optical characteristic of a light emitted from a surface emitting element including a light emitting layer, a characteristic layer that is disposed on an optical path of light generated in the light emitting layer and has variability in an optical characteristic due to voltage application, a plurality of electrodes including a first electrode and a second electrode provided on the characteristic layer, and a third electrode disposed on a side opposite to the characteristic layer of the light emitting layer, the method including
applying a potential to one of the first electrode or the second electrode to generate a potential difference between the first electrode and the second electrode, and applying a potential substantially the same as the potential to the third electrode to inject carriers into the characteristic layer, and
driving the surface emitting element by generating a potential difference between at least one of the first electrode or the second electrode and the third electrode.

### BRIEF DESCRIPTION OF DRAWINGS

FIG. 1 is a sectional view of a surface emitting element according to a first embodiment of the present technology.

FIG. 2 is a plan view of the surface emitting element in FIG. 1.

FIG. 3 is a block diagram illustrating a functional configuration example of an optical characteristic detection device.

FIG. 4 is a flowchart for describing optical characteristic detection processing 1.

FIGS. 5A to 5C are timing charts for describing the optical characteristic detection processing 1.

FIG. 6 is a flowchart for describing optical characteristic detection processing 2.

FIGS. 7A to 7C are timing charts for describing the optical characteristic detection processing 2.

FIG. 8 is a block diagram illustrating a functional configuration example of the optical characteristic adjustment device.

FIG. 9 is a flowchart for describing optical characteristic adjustment processing.

FIGS. 10A to 10C are timing charts for describing the optical characteristic detection processing.

FIG. 11 is a flowchart for describing an example of a method for manufacturing the surface emitting element in FIG. 1.

FIG. 12 is a sectional view illustrating a first process in FIG. 11.

FIG. 13 is a sectional view illustrating a second process in FIG. 11.

FIG. 14 is a sectional view illustrating a third process in FIG. 11.

FIG. 15 is a sectional view illustrating a fourth process in FIG. 11.

FIG. 16 is a sectional view illustrating a fifth process in FIG. 11.

FIG. 17 is a sectional view illustrating a sixth process in FIG. 11.

FIG. 18 is a sectional view illustrating a seventh process in FIG. 11.

FIG. 19 is a sectional view illustrating an eighth process in FIG. 11.

FIG. 20 is a sectional view illustrating a ninth process in FIG. 11.

FIG. 21 is a sectional view of a surface emitting element according to Modification 1 of the first embodiment of the present technology.

FIG. 22 is a flowchart for describing an example of a method for manufacturing the surface emitting element in FIG. 21.

FIG. 23 is a sectional view illustrating a second process in FIG. 22.

FIG. 24 is a sectional view illustrating a third process in FIG. 22.

FIG. 25 is a sectional view illustrating a fourth process in FIG. 22.

FIG. 26 is a sectional view illustrating a fifth process in FIG. 22.

FIG. 27 is a sectional view illustrating a sixth process in FIG. 22.

FIG. 28 is a sectional view illustrating a seventh process in FIG. 22.

FIG. 29 is a sectional view illustrating an eighth process in FIG. 22.

FIG. 30 is a sectional view of a surface emitting element according to Modification 2 of the first embodiment of the present technology.

FIG. 31 is a flowchart for describing an example of a method for manufacturing the surface emitting element in FIG. 30.

FIG. 32 is a sectional view illustrating a second process in FIG. 31.

FIG. 33 is a sectional view illustrating a third process in FIG. 31.

FIG. 34 is a sectional view illustrating a fourth process in FIG. 31

FIG. 35 is a sectional view illustrating a fifth process in FIG. 31.

FIG. 36 is a sectional view illustrating a sixth process in FIG. 31.

FIG. 37 is a sectional view illustrating a seventh process in FIG. 31.

FIG. 38 is a sectional view illustrating an eighth process in FIG. 31

FIG. 39 is a sectional view illustrating a ninth process in FIG. 31.

FIG. 40 is a sectional view of a surface emitting element according to Modification 3 of the first embodiment of the present technology.

FIG. 41 is a sectional view of a surface emitting element according to a second embodiment of the present technology.

FIG. 42 is a flowchart for describing an example of a method for manufacturing the surface emitting element in FIG. 41.

FIG. 43 is a sectional view illustrating a third process in FIG. 42.

FIG. 44 is a sectional view illustrating a fourth process in FIG. 42.

FIG. 45 is a sectional view illustrating a fifth process in FIG. 42.

FIG. 46 is a sectional view illustrating a sixth process in FIG. 42.

FIG. 47 is a sectional view illustrating a seventh process in FIG. 42.

FIG. 48 is a sectional view illustrating an eighth process in FIG. 42.

FIG. 49 is a sectional view of a surface emitting element according to Modification 1 of the second embodiment of the present technology.

FIG. 50 is a sectional view of a surface emitting element according to Modification 2 of the second embodiment of the present technology.

FIG. 51 is a sectional view of a surface emitting element according to a third embodiment of the present technology.

FIG. 52 is a flowchart for describing an example of a method for manufacturing the surface emitting element in FIG. 51.

FIG. 53 is a sectional view illustrating a first process in FIG. 52.

FIG. 54 is a sectional view illustrating a second process in FIG. 52.

FIG. 55 is a sectional view illustrating a third process in FIG. 52.

FIG. 56 is a sectional view illustrating a fourth process in FIG. 52.

FIG. 57 is a sectional view illustrating a fifth process in FIG. 52.

FIG. 58 is a sectional view illustrating a sixth process in FIG. 52.

FIG. 59 is a sectional view illustrating a seventh process in FIG. 52.

FIG. 60 is a sectional view illustrating an eighth process in FIG. 52.

FIG. 61 is a sectional view illustrating a ninth process in FIG. 52.

FIG. 62 is a sectional view of a surface emitting element according to Modification of the third embodiment of the present technology.

FIG. 63 is a sectional view of a surface emitting element according to a fourth embodiment of the present technology.

FIG. 64 is a flowchart for describing an example of a method for manufacturing the surface emitting element in FIG. 63.

FIG. 65 is a sectional view illustrating a fourth process in FIG. 64.

FIG. 66 is a sectional view illustrating a fifth process in FIG. 64.

FIG. 67 is a sectional view illustrating a sixth process in FIG. 64.

FIG. 68 is a sectional view illustrating a seventh process in FIG. 64.

FIG. 69 is a sectional view illustrating an eighth process in FIG. 64.

FIG. 70 is a sectional view of a surface emitting element according to a fifth embodiment of the present technology.

FIG. 71 is a flowchart for describing an example of a method for manufacturing the surface emitting element in FIG. 70.

FIG. 72 is a sectional view illustrating a third process in FIG. 71.

FIG. 73 is a sectional view illustrating a fourth process in FIG. 71.

FIG. 74 is a sectional view illustrating a fifth process in FIG. 71.

FIG. 75 is a sectional view illustrating a sixth process in FIG. 71.

FIG. 76 is a sectional view illustrating a seventh process in FIG. 71.

FIG. 77 is a sectional view illustrating an eighth process in FIG. 71.

FIG. 78 is a sectional view illustrating a ninth process in FIG. 71.

FIG. 79 is a sectional view of a surface emitting element according to Modification 1 of the fifth embodiment of the present technology.

FIG. 80 is a sectional view of a surface emitting element according to Modification 2 of the fifth embodiment of the present technology.

FIG. 81 is diagram illustrating Example 1 of a characteristic layer of the surface emitting element of the present technology.

FIG. 82 is diagram illustrating Example 2 of a characteristic layer of the surface emitting element of the present technology.

FIG. 83 is diagram illustrating Example 3 of a characteristic layer of the surface emitting element of the present technology.

FIG. 84 is diagram illustrating Example 4 of a characteristic layer of the surface emitting element of the present technology.

FIG. 85 is diagram illustrating Example of first and second electrodes of the surface emitting element of the present technology.

FIG. 86 is diagram illustrating Example 1 of first and second electrode groups of the surface emitting element of the present technology.

FIGS. 87A to 87F are diagrams illustrating variations of a lateral mode.

FIG. 88 is diagram illustrating Example 2 of the first and second electrode groups of the surface emitting element of the present technology.

FIG. 89 is a diagram illustrating an application example of the surface emitting element of the present technology to a distance measuring device.

FIG. 90 is a block diagram illustrating an example of a schematic configuration of a vehicle control system.

FIG. 91 is an explanatory diagram illustrating an example of an installation position of the distance measuring device.

### MODES FOR CARRYING OUT THE INVENTION

Hereinafter, preferred embodiments of the present technology will be described in detail with reference to the accompanying drawings. Note that, in this specification and the drawings, the components having substantially the same functional configuration are assigned with the same reference sign, and the description thereof is not repeated. The embodiments described below illustrate representative embodiments of the present technology, and the scope of the present technology is not narrowly interpreted by these embodiments. Even in a case where this specification describes that a surface emitting element, a method for detecting an optical characteristic, and a method for adjusting an optical characteristic of the present technology exhibit a plurality of effects, the surface emitting element, the method for detecting an optical characteristic, and the method for adjusting an optical characteristic of the present technology are only required to exhibit at least one effect. The effects described herein are merely examples and are not restrictive, and other effects may be provided.

Furthermore, description will be given in the following order.
1. Introduction
2. Surface emitting element according to first embodiment of present technology
   (1) Configuration of surface emitting element
   (2) Basic operation of surface emitting element
   (3) Functional example of optical characteristic detection device
   (4) Optical characteristic detection processing 1
   (5) Optical characteristic detection processing 2
   (6) Functional example of optical characteristic adjustment device
   (7) Optical characteristic adjustment processing
   (8) Example of method for manufacturing surface emitting element
   (9) Effects of surface emitting element and method for manufacturing the same
3. Surface emitting element according to Modifications 1 to 3 of first embodiment of present technology
4. Surface emitting element according to second embodiment of present technology
5. Surface emitting element according to Modifications 1 and 2 of second embodiment of present technology
6. Surface emitting element according to third embodiment of present technology
7. Surface emitting element according to
Modification of third embodiment of present technology
8. Surface emitting element according to fourth
embodiment of present technology
9. Surface emitting element according to fifth
embodiment of present technology
10. Surface emitting element according to
Modifications 1 and 2 of fifth embodiment of present
technology
11. Examples 1 to 4 of characteristic layer of
surface emitting element of present technology.
12. Example of first and second electrodes and
Examples 1 and 2 of first and second electrode groups of
surface emitting element of present technology
13. Modifications of present technology
14. Application example to electronic device
15. Example in which surface emitting element is
applied to distance measuring device
16. Example in which distance measuring device is
installed on mobile body

1. Introduction

Conventionally, for example, as an end surface emitting laser, there is a mass production technology represented by a 405 nm Blu-ray (registered trademark) reproducing laser.

In the reproducing laser, for example, light leaking from a rear end face is detected by a photodiode (PD) disposed on the rear end face in order to monitor an optical characteristic (for example, a light amount) of an emitted light. In this case, there are problems such as deterioration of light emission characteristics due to additional optical loss, increase in the number of components for the PD provided, and occurrence of an additional process of mounting the PD.

On the other hand, for example, a surface emitting laser (surface emitting element) has a configuration for emitting light in a direction perpendicular to a substrate, and thus is more difficult to be provided with a PD than an end surface emitting laser.

In addition, it is extremely effective in practical use for a light source such as a semiconductor laser and the like including an end surface emitting laser and a surface emitting laser to have a function of adjusting the optical characteristic of the emitted light.

Therefore, the present inventors have developed the surface emitting element of the present technology as a surface emitting element capable of detecting the optical characteristic of the emitted light and/or adjusting the optical characteristic of the emitted light without providing an additional component such as a PD outside.

2. Surface Emitting Element According to First Embodiment of Present Technology

(1) Configuration of Surface Emitting Element

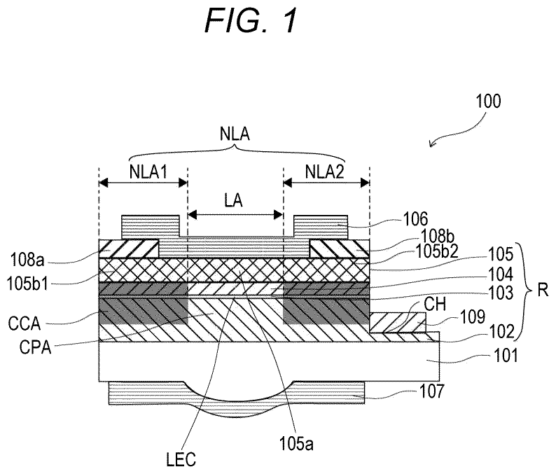

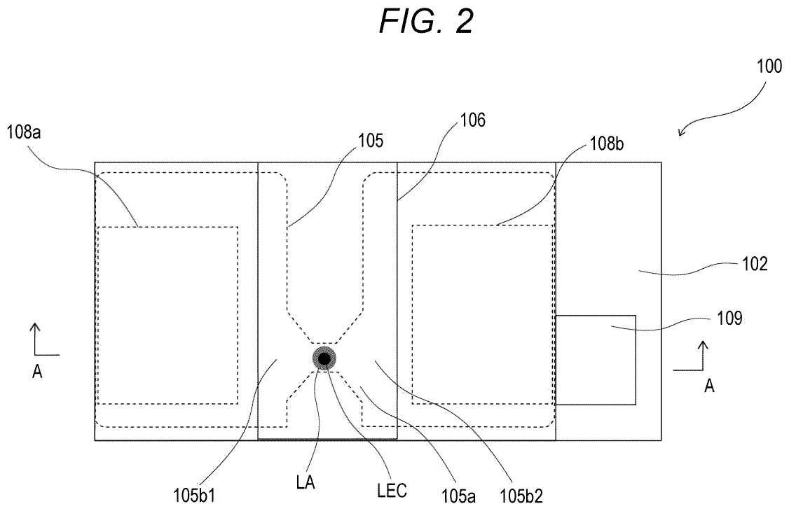

FIG. 1 is a sectional view illustrating a configuration of a surface emitting element 100 according to a first embodiment of the present technology. FIG. 2 is a plan view of the surface emitting element 100. FIG. 1 is a sectional view taken along line A-A in FIG. 2. Hereinafter, for the sake of convenience, the upper part in the sectional view of FIG. 1 and the like will be described as an upper side, and the lower part in the sectional view of FIG. 1 and the like will be described as a lower side.

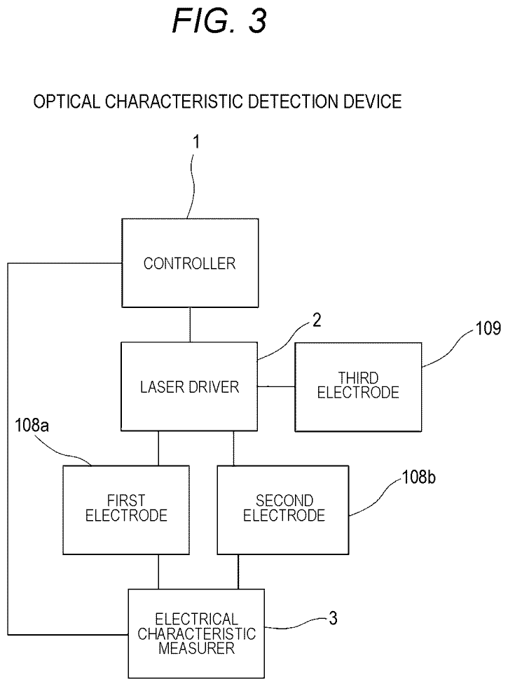

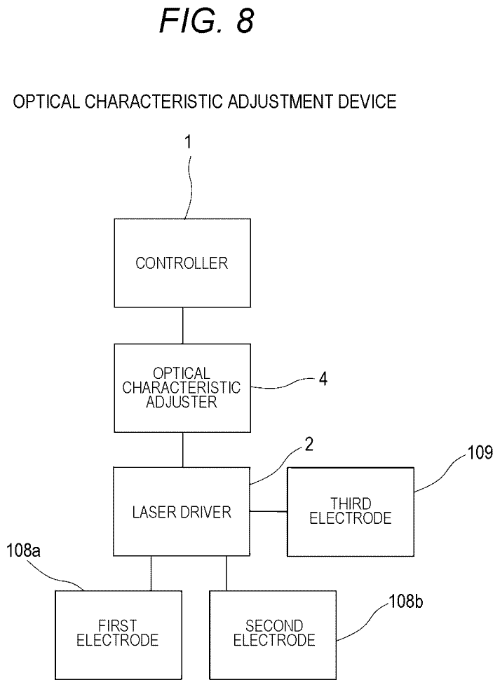

The surface emitting element 100 is, for example, a GaN-based surface emitting laser (VCSEL). The surface emitting element 100 is driven by, for example, a laser driver 2 (see FIGS. 3 and 8).

As shown in FIG. 1, the surface emitting element 100 includes, as an example, a light emitting layer 103, a characteristic layer 105, and a plurality of (for example, two) electrodes (for example, first and second electrodes 108a and 108b). The surface emitting element 100 further includes, as an example, a substrate 101, first and second reflectors 106 and 107, first and second cladding layers 104 and 102, and a third electrode 109.

In the surface emitting element 100, the second cladding layer 102, the light emitting layer 103, the first cladding layer 104, the characteristic layer 105, and the first reflector 106 are disposed in this order on a front surface (upper surface) of the substrate 101, and the second reflector 107 is provided on a back surface (lower surface) of the substrate 101.

In the surface emitting element 100, as an example, the light emitting layer 103, the first and second cladding layers 104 and 102, and the characteristic layer 105 constitute a resonator R.

As an example, the surface emitting element 100 emits light from an upper surface (emission surface) of the first reflector 106. That is, as an example, the surface emitting element 100 is a front surface emitting type surface emitting laser.

[Substrate]

The substrate 101 is, as an example, a Gan substrate.

[Resonator]

As can be seen from the above description, the resonator R is disposed between the first and second reflectors 106 and 107.

At least a part (for example, a peripheral part of the first cladding layer 104, a peripheral part of the light emitting layer 103, an upper part of a peripheral part of the second cladding layer 102, and a part painted in gray in FIG. 1) in a thickness direction of a peripheral part of the resonator R is a high electrical resistance region having higher electrical resistance (region having lower carrier conductivity) than a central part surrounded by the at least a part. That is, the high electrical resistance region constitutes a current confinement region CCA, and the central part constitutes a current passage region CPA (region having higher carrier conductivity).

The current confinement region CCA is formed by implanting a high concentration of ions (for example, B⁺⁺, H⁺⁺, and the like).

(Light emitting layer) As an example, the light emitting layer 103 has a five-layered multiple-quantum well structure in which an In_{0.04}Ga_{0.96} N layer (barrier layer) and an In_{0.16}Ga_{0.84} N layer (well layer) are stacked. The light emitting layer 103 is also referred to as an “active layer”.

The light emitting layer 103 has a light emitting region LA and a non-light emitting region NLA surrounding the light emitting region LA. The light emitting region LA is a region of the light emitting layer 103 into which current is injected and which emits light, and is a region corresponding to the current passage region CPA. The non-light emitting region NLA is a region of the light emitting layer 103 into which current is not injected, and is a region corresponding to the current confinement region CCA.

(First and Second Cladding Layers)

The first and second cladding layers 104 and 102 are disposed so as to sandwich the light emitting layer 103. The first cladding layer 104 is disposed on one surface side (an upper surface side) of the light emitting layer 103, and the second cladding layer 102 is disposed on the other surface side (a lower surface side) of the light emitting layer 103.

The first cladding layer 104 includes, for example, a p-GaN layer, and the second cladding layer 102 includes, for example, an n-GaN layer.

[First and Second Reflectors]

As an example, the first and second reflectors 106 and 107 are disposed at positions sandwiching the resonator R (positions sandwiching the light emitting layer 103).

The first reflector 106 is disposed on the one surface side (the upper surface side) of the light emitting layer 103. Specifically, the first reflector 106 is provided on one surface (an upper surface) of the characteristic layer 105.

The second reflector 107 is disposed on the other surface side (the lower surface side) of the light emitting layer 103. Specifically, the second reflector 107 is provided on the back surface (the lower surface) of the substrate 101.

As an example, each of the first and second reflectors 106 and 107 is a dielectric multilayer film reflector including a layered structure of a Ta₂O₅ layer and a SiO₂ layer (a total number of laminated dielectric films: 20).

A reflectance of the second reflector 107 is set to be slightly higher than a reflectance of the first reflector 106.

[First and Second Electrodes]

Each of the first and second electrodes 108a and 108b is an independent electrode (separated from each other).

The first and second electrodes 108a and 108b are provided on the characteristic layer 105 as shown as an example in FIGS. 1 and 2. Specifically, as an example, the first and second electrodes 108a and 108b are provided on a surface (the upper surface) of the characteristic layer 105 closer to the first reflector 106.

As an example, the first and second electrodes 108a and 108b are disposed apart from each other along the characteristic layer 105.

The first electrode 108a is disposed at a position corresponding to a section NLA1 on one side of both sides sandwiching the light emitting region LA in the non-light emitting region NLA of the light emitting layer 103.

The second electrode 108b is disposed at a position corresponding to a section NLA2 on the other side of both sides sandwiching the light emitting region LA in the non-light emitting region NLA of the light emitting layer 103.

At least one of the first or second electrode 108a or 108b can also serve as, for example, an electrode (anode electrode) for supplying current to the light emitting layer 103. In this case, at least one of the first or second electrode 108a or 108b is connected to, for example, an anode (positive electrode) of the laser driver 2 (see FIGS. 3 and 8).

An end of the first reflector 106 is disposed on an inner part of the first and second electrodes 108a and 108b facing each other, while an outer part of each of the first and second electrodes 108a and 108b is exposed, and the outer part serves as an electrical contact with wiring and the like.

Each of the first and second electrodes 108a and 108b may have a single-layer structure or a layered structure.

Each of the first and second electrodes 108a and 108b includes, for example, at least one type of metal (including an alloy) selected from a group including Au, Ag, Pd, Pt, Ni, Ti, V, W, Cr, Al, Cu, Zn, Sn, and In.

In a case where having a layered structure, each of the first and second electrodes 108a and 108b includes a material such as, for example, Ti/Au, Ti/Al, Ti/Al/Au, Ti/Pt/Au, Ni/Au, Ni/Au/Pt, Ni/Pt, Pd/Pt, or Ag/Pd.

[Third Electrode]

The third electrode 109 is provided in a contact hole CH formed in the second cladding layer 102 so as to be in contact with the second cladding layer 102. In a lower part of the current passage region CPA of the second cladding layer 102, there is a current path through which current flows in a direction including an in-plane direction.

The third electrode 109 can be used as, for example, an electrode (cathode electrode) for flowing out the current supplied to the light emitting layer 103. In this case, the third electrode 109 is connected to, for example, a cathode (negative electrode) of the laser driver 2 (see FIGS. 3 and 8).

The third electrode 109 may have a single-layer structure or a layered structure.

The third electrode 109 includes, for example, at least one type of metal (including an alloy) selected from a group including Au, Ag, Pd, Pt, Ni, Ti, V, W, Cr, Al, Cu, Zn, Sn, and In.

In a case where having a layered structure, the third electrode 109 contains a material such as, for example, Ti/Au, Ti/Al, Ti/Al/Au, Ti/Pt/Au, Ni/Au, Ni/Au/Pt, Ni/Pt, Pd/Pt, or Ag/Pd.

[Characteristic Layer]

The characteristic layer 105 is disposed on an optical path of light generated in the light emitting layer 103. The characteristic layer 105 and the light emitting layer 103 are stacked on each other. That is, the characteristic layer 105 and the light emitting layer 103 are integrated in a monolithic manner. The thickness (film thickness) of the characteristic layer 105 is set to be substantially constant, as an example.

As an example, the characteristic layer 105 is disposed so as to overlap at least a position LEC (for example, a central part of the light emitting region LA) having the highest light emission intensity in an in-plane direction of the light emitting region LA of the light emitting layer 103. Specifically, as an example, the characteristic layer 105 is disposed so as to overlap the light emitting region LA and the non-light emitting region NLA of the light emitting layer 103.

The characteristic layer 105 is disposed between the first reflector 106 and the light emitting layer 103. Specifically, the characteristic layer 105 is disposed between the first reflector 106 and the first cladding layer 104 and constitutes the uppermost layer of the resonator R.

The characteristic layer 105 is, for example, a transparent conductive film including ITO, ITiO, ZnO, or the like.

The transparent conductive film as the characteristic layer 105 has high carrier conductivity, and particularly plays a role of facilitating injection of carriers (for example, holes) flowing in from at least one of the first or second electrode 108a or 108b into the light emitting layer 103 in the GaN-based surface emitting element.

The transparent conductive film as the characteristic layer 105 exhibits an electrical characteristic due to light incidence and has variability in an optical characteristic due to voltage application.

The transparent conductive film as the characteristic layer 105 exhibits, as an example, a characteristic in which electrical resistance changes in accordance with a change in an amount of incident light as an electrical characteristic due to light incidence. Specifically, when light is incident on the transparent conductive film, the transparent conductive film absorbs a part of the light, generates carriers, and changes the electrical resistance. More specifically, the electrical resistance of the transparent conductive film decreases as the amount of incident light increases.

Therefore, the amount of incident light can be indirectly measured by measuring the electrical resistance of the transparent conductive film as the characteristic layer 105.

The transparent conductive film as the characteristic layer 105 has, for example, a characteristic in which a light absorption end is shifted to a short wavelength side or a long wavelength side by voltage application as the variability in the optical characteristic by voltage application.

The electrical resistance R in the in-plane direction (specifically, a direction parallel to an arrangement direction of the first and second electrodes 108a and 108b) of the transparent conductive film as the characteristic layer 105 is represented by R=R1+R2+R3.
R1: electrical resistance between a region 105b1 (see FIG. 2) corresponding to the first electrode 108a in the characteristic layer 105 and a region 105a (see FIG. 2) corresponding to the light emitting region LA in the characteristic layer 105
R2: electrical resistance of the region 105a corresponding to the light emitting region LA in the characteristic layer 105
R3: electrical resistance between a region 105b2 corresponding to the second electrode 108b in the characteristic layer 105 and the region 105a corresponding to the light emitting region LA in the characteristic layer 105

Hereinafter, the region 105a of the characteristic layer 105 is also referred to as “central region 105a”, the region 105b1 of the characteristic layer 105 is also referred to as “first peripheral region 105b1”, and the region 105b2 of the characteristic layer 105 is also referred to as “second peripheral region 105b2”.

Among R1 to R3, since the electrical resistance that changes depending on the amount of light generated in the light emitting layer 103 is R2, it is desirable that a detection sensitivity of the change in R2 is high, that is, an absolute value of R2 is larger than R1 and R3 in order to accurately detect a change amount (ΔR2) of R2. Therefore, an area of a cross section of the characteristic layer 105 orthogonal to the arrangement direction of the first and second electrodes 108a and 108b is desirably smaller in the central region 105a than in each of the first and second peripheral regions 105b1 and 105b2.

That is, under the condition that the thickness of the characteristic layer 105 is constant, a size (for example, a length in a direction orthogonal to the arrangement direction of the first and second electrodes 108a and 108b) of the central region 105a is desirably smaller than a size (for example, a length in a direction orthogonal to the arrangement direction of the first and second electrodes 108a and 108b) of each of the first and second peripheral regions 105b1 and 105b2 in plan view.

As shown in FIG. 2 as an example, in the characteristic layer 105, the central region 105a is smaller than each of the first and second peripheral regions 105b1 and 105b2 in plan view.

Specifically, as shown in FIG. 2 as an example, the length of the characteristic layer 105 in the direction orthogonal to the arrangement direction of the first and second electrodes 108a and 108b in plan view is shorter in the central region 105a than in the first and second peripheral regions 105b1 and 105b2.

Furthermore, as an example, in the central region 105a of the characteristic layer 105, the size of a part corresponding to the position LEC having the highest light emission intensity in the light emitting region LA is the smallest in plan view. As a result, the detection sensitivity of the change in R2 can be enhanced as much as possible.

Specifically, the central region 105a of the characteristic layer 105 has a shape (for example, a tapered shape, a curved shape, or the like) in which a width becomes narrower as approaching a position corresponding to the position LEC in plan view. As a result, in the central region 105a, the detection sensitivity of R2 becomes higher at a position closer to the position corresponding to the position LEC, and is the highest at the position corresponding to the position LEC.

(2) Basic Operation of Surface Emitting Element

In the surface emitting element 100, for example, the current supplied from the anode of the laser driver 2 (see FIGS. 3 and 8) and flowing in from at least one of the first or second electrode 108a or 108b passes through the characteristic layer 105, is narrowed in the current confinement region CCA, passes through an upper part of the current passage region CPA, and is injected into the light emitting region LA of the light emitting layer 103, and the light emitting region LA emits light. The current injected into the light emitting region LA reaches the third electrode 109 via a lower part of the current passage region CPA and a lower part of the second cladding layer 102, and flows out from the third electrode 109 to, for example, the cathode of the laser driver 2. The light generated in the light emitting layer 103 reciprocates between the first and second reflectors 106 and 107. During the reciprocation, a part of the light is absorbed by the characteristic layer 105 and amplified by the light emitting layer 103. When an oscillation condition is satisfied, the light is emitted as laser light from the upper surface (emission surface) of the first reflector 106.

(3) Functional Example of Optical Characteristic Detection Device

FIG. 3 is a block diagram illustrating a functional example of an optical characteristic detection device that detects an optical characteristic of a light emitted from the surface emitting element 100.

The optical characteristic detection device includes a controller 1, the laser driver 2, and an electrical characteristic measurer 3.

The controller 1 controls the laser driver 2 and acquires a measurement result in the electrical characteristic measurer 3. The controller 1 is implemented by hardware including, for example, a CPU and a chip set.

The laser driver 2 includes a plurality of (for example, two) anode terminals to which the first and second electrodes 108a and 108b of the surface emitting element 100 are individually connected via wiring, and a cathode terminal to which the third electrode 109 is connected via wiring. That is, the laser driver 2 can individually apply potentials to the first and second electrodes 108a and 108b. The laser driver 2 includes, for example, circuit elements such as a capacitor and a transistor.

The electrical characteristic measurer 3 is connected to the first and second electrodes 108a and 108b. As an example, the electrical characteristic measurer 3 includes a resistance measuring device, and measures the electrical resistance R of the characteristic layer 105.

(4) Optical Characteristic Detection Processing 1

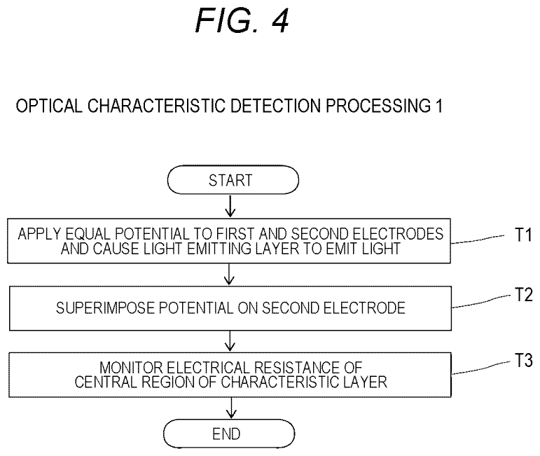

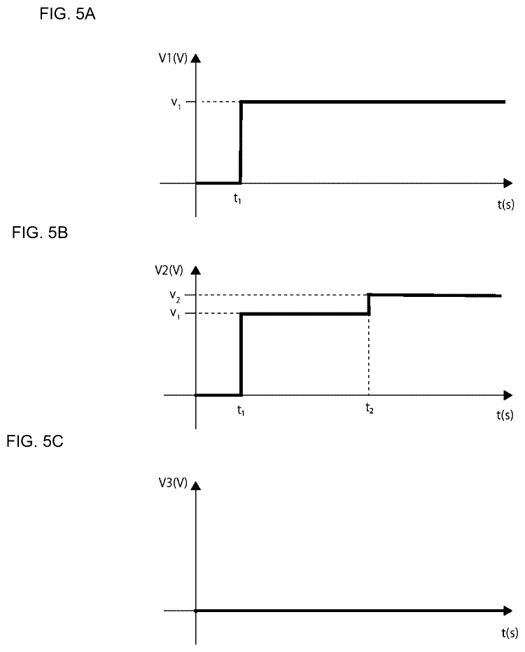

Hereinafter, optical characteristic detection processing 1 performed by using the optical characteristic detection device will be described with reference to the flowchart (steps T1 to T3) in FIG. 4 and the timing chart in FIG. 5. In the optical characteristic detection processing 1, as shown in FIG. 5C, a potential V3 of the third electrode 109 is maintained at 0 throughout.

In the first step T1, the controller 1 controls the laser driver 2 to apply an equal potential to the first and second electrodes 108a and 108b (where, for example, potential V1 of the first electrode 108a and a potential V2 of the second electrode 108b are v₁) from timing t₁ and cause the light emitting layer 103 to emit light (see FIGS. 5A and 5B). As a result, light (emitted light) generated in the light emitting layer 103 is incident on the transparent conductive film as the characteristic layer 105.

In the next step T2, the controller 1 controls the laser driver 2 to set the potential V2 of the second electrode 108b to v₂ (>v₁) from timing t₂, that is, to superimpose a potential Δv (=v₂−v₁) on the second electrode 108b (see FIG. 5(B)). As a result, a potential difference Δv is generated between the first and second electrodes 108a and 108b.

In the final step T3, the controller 1 indirectly monitors the optical characteristic (for example, the amount) of the light generated in the light emitting layer 103 by monitoring the measurement result of the electrical resistance R of the characteristic layer 105 (measurement result in the electrical characteristic measurer 3) after timing t₂.

For example, when R varies (the amount of light varies) during monitoring of R (during monitoring of the amount of light), the controller 1 can control a potential to be applied to at least one of the first or second electrode 108a or 108b (automatic power control (APC)) so that R becomes a predetermined value (so that the amount of the emitted light becomes a predetermined value).

Note that, since the first and second electrodes 108a and 108b have substantially the same function, the optical characteristic detection processing 1 can be similarly performed even if the roles of the first and second electrodes 108a and 108b are switched.

In addition, in step T2, different potentials may be superimposed on the first and second electrodes 108a and 108b from timing t₂ to generate a potential difference between the first and second electrodes 108a and 108b.

(5) Optical Characteristic Detection Processing 2

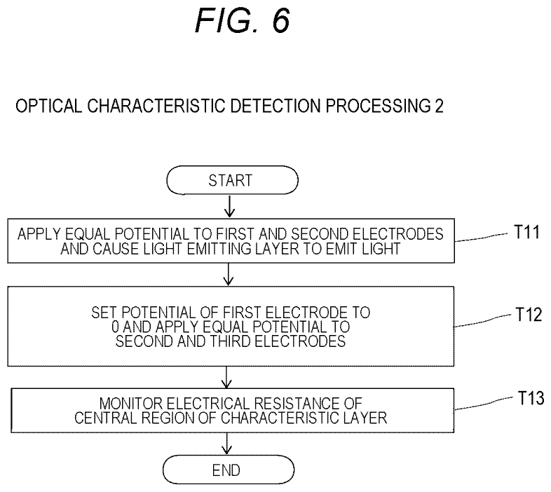

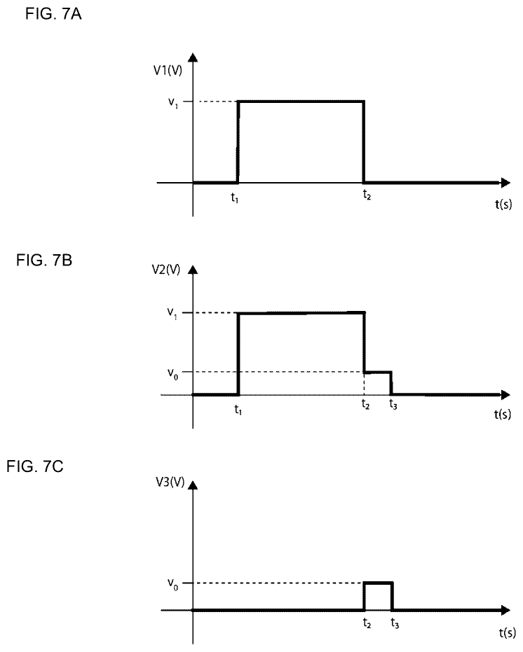

Hereinafter, optical characteristic detection processing 2 performed by using the optical characteristic detection device will be described with reference to the flowchart in FIG. 6 and the timing chart in FIG. 7.

In the first step T11, the controller 1 controls the laser driver 2 to apply an equal potential (first potential v₁) to the first and second electrodes 108a and 108b from timing t₁ and cause the light emitting layer 103 to emit light (see FIGS. 7A and 7B). As a result, light (emitted light) generated in the light emitting layer 103 is incident on the transparent conductive film as the characteristic layer 105.

In the next step T12, the controller 1 controls the laser driver 2 to set the potential V1 of the first electrode 108a to 0 from timing t₂, and to set the potential V2 of the second electrode 108b and the potential V3 of the third electrode 109 to v₀ from timing t₂ to t₃, that is, to apply an equal potential (v₀) to the second electrode 108b and the third electrode 109. As a result, after timing t₂, the light emitting layer 103 does not emit light, and carriers (for example, holes) flow out from the characteristic layer 105 to the cathode terminal of the laser driver 2 from the third electrode 109.

In the final step T13, the controller 1 indirectly monitors the optical characteristic (for example, the amount) of the light generated in the light emitting layer 103 by monitoring the measurement result of the electrical resistance R of the characteristic layer 105 (measurement result in the electrical characteristics measurer 3) while the carriers remain in the characteristic layer 105 after timing t₂ (while the amount of light generated in the light emitting layer 103 can be measured).

For example, when R varies (the amount of light varies) during monitoring of R (during monitoring of the amount of light), the controller 1 can control a potential to be applied to at least one of the first or second electrode 108a or 108b (automatic power control (APC)) so that R becomes a predetermined value (so that the amount of light becomes a predetermined value).

Note that, since the first and second electrodes 108a and 108b have substantially the same function, the optical characteristic detection processing 2 can be similarly performed even if the roles of the first and second electrodes 108a and 108b are switched.

(6) Functional Example of Optical Characteristic Adjustment Device

FIG. 8 is a block diagram illustrating a functional example of an optical characteristic adjustment device that adjusts an optical characteristic of a light emitted from the surface emitting element 100.

The optical characteristic adjustment device includes the controller 1, the laser driver 2, and an optical characteristic adjuster 4.

The controller 1 controls the laser driver 2 via the optical characteristic adjuster 4. The optical characteristic adjuster 4 adjusts the potential applied to the first electrode 108a, the second electrode 108b, and the third electrode 109 by the laser driver 2 by adjusting a control signal supplied to the laser driver 2 in response to a request from the controller 1. The controller 1 and the optical characteristic adjuster 4 are implemented by hardware including, for example, a CPU and a chip set.

The laser driver 2 includes a plurality of (for example, two) anode terminals to which the first and second electrodes 108a and 108b of the surface emitting element 100 are individually connected, and a cathode terminal to which the third electrode 109 is connected. That is, the laser driver 2 can individually apply potentials to the first and second electrodes 108a and 108b. The laser driver 2 includes, for example, circuit elements such as a capacitor and a transistor.

(7) Optical Characteristic Adjustment Processing

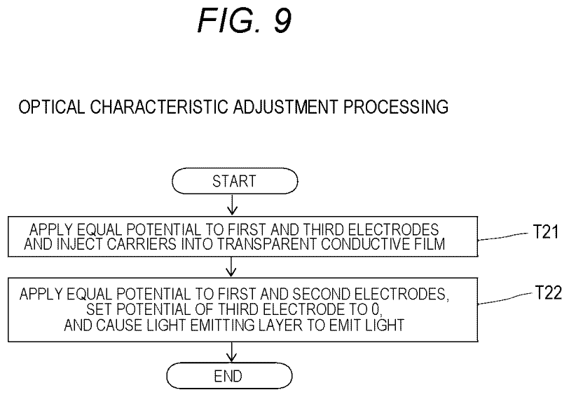

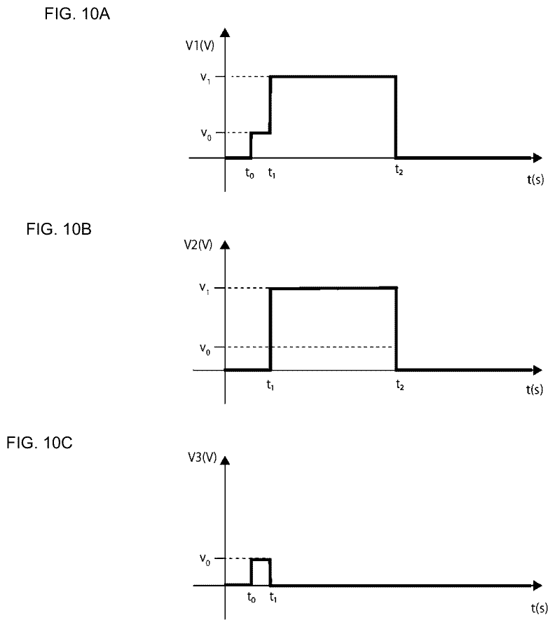

Hereinafter, optical characteristic adjustment processing 1 performed by using the optical characteristic adjustment device will be described with reference to the flowchart (steps T21 and T22) in FIG. 9 and the timing chart in FIG. 10.

In the first step T21, the controller 1 controls the laser driver 2 via the optical characteristic adjuster 4 to apply the equal potential v₀ to the first and third electrodes 108a and 109 (where, for example, the potential V1 of the first electrode 108a and the potential V3 of the third electrode 109 are v₀) from timing t₀ to timing t₁ (see FIGS. 10A and 10C). As a result, carriers are injected (replenished and filled) into the transparent conductive film as the characteristic layer 105 in a state where the light emitting layer 103 does not emit light. The optical characteristic of the transparent conductive film into which the carriers are injected change (specifically, the light absorption end is shifted to the short wavelength side due to the Burstein-Moss effect). In this case, a threshold current Ith of the surface emitting element 100 can be reduced.

In the final step T22, the controller 1 controls the laser driver 2 via the optical characteristic adjuster 4 to apply the equal potential v₁ to the first and second electrodes 108a and 108b (where, for example, the potential V1 of the first electrode 108a and the potential V2 of the second electrode 108b are v₁) and set the voltage V3 of the third electrode 109 to 0 from timing t₁ to timing t₂ and causes the light emitting layer 103 to emit light (see FIGS. 10A to 10C). As a result, when the light generated in the light emitting layer 103 passes through the characteristic layer 105 (the transparent conductive film into which the carriers are injected), the optical characteristic of the characteristic layer 105 is adjusted, and eventually, the optical characteristic of the emitted light is adjusted.

Note that, since the first and second electrodes 108a and 108b have substantially the same function, the optical characteristic adjustment processing can be similarly performed even if the roles of the first and second electrodes 108a and 108b are switched.

(8) Example of Method for Manufacturing Surface Emitting Element

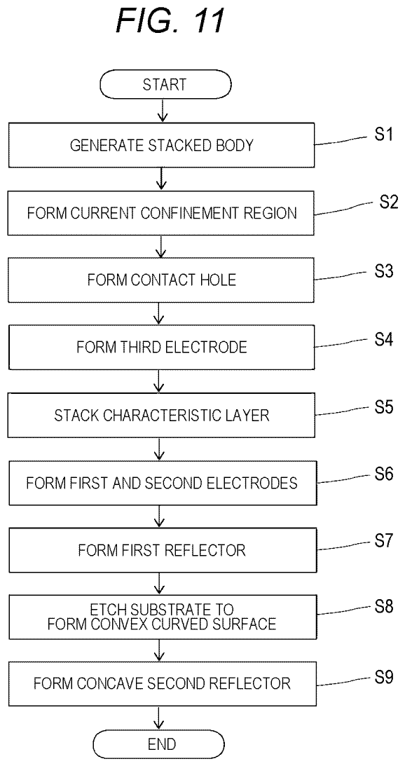

Hereinafter, an example of a method for manufacturing the surface emitting element 100 will be described with reference to the flowchart (steps S1 to S9) in FIG. 11. Here, as an example, a plurality of the surface emitting elements 100 is generated at a time on one wafer as a base material of the substrate 101 by a semiconductor manufacturing method using a semiconductor manufacturing device. Next, the plurality of surface emitting elements 100 integrated in series is separated from each other to obtain a plurality of chip-shaped surface emitting elements 100 (surface emitting element chips). Note that, by the semiconductor manufacturing method using the semiconductor manufacturing device, it is also possible to simultaneously generate a plurality of surface emitting element arrays in which a plurality of the surface emitting elements 100 is two-dimensionally arranged on one wafer as a base material of the substrate 101, separate a series of integrated plurality of surface emitting element arrays from each other, and obtain a plurality of chip-shaped surface emitting element arrays (surface emitting element array chips).

As an example, the surface emitting element 100 is manufactured by a CPU of the semiconductor manufacturing device by following the procedure of the flowchart in FIG. 11.

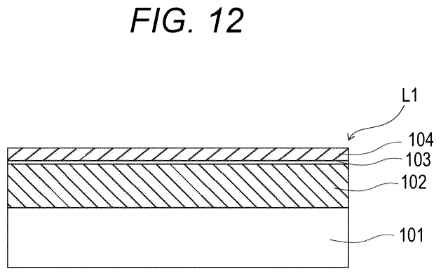

In the first step S1, a stacked body L1 is generated (see FIG. 12). Specifically, the second cladding layer 102, the light emitting layer 103, and the first cladding layer 104 are stacked (epitaxially grown) in this order on the substrate 101 (for example, a GaN substrate) in a growth chamber by a metal organic chemical vapor deposition method (MOCVD method) or a molecular beam epitaxy method (MBE method) to generate the stacked body L1.

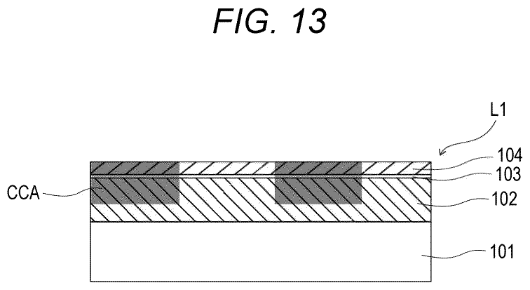

In the next step S2, the current confinement region CCA is formed (see FIG. 13). Specifically, a region where the current confinement region CCA of the stacked body L1 is not formed (for example, a region to be the current passage region CPA and a region where the contact hole CH is formed) is protected by a protective film including resist, SiO₂, or the like, and ions (for example, B⁺⁺) are implanted from a side of the first cladding layer 104 into a circling region (for example, an annular region) of the stacked body L1 not protected by the protective film. The depth of the ion implantation at this time is up to a part (the upper part) of the second cladding layer 102.

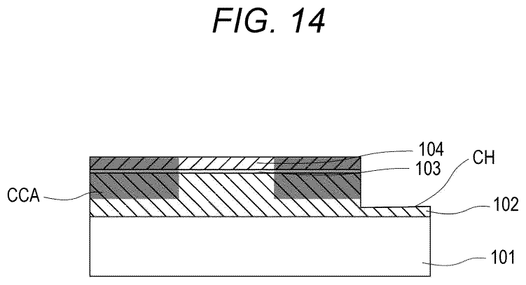

In the next step S3, the contact hole CH is formed (see FIG. 14). Specifically, one side of the current confinement region CCA of the stacked body L1 (see FIG. 13) is etched by, for example, dry etching or wet etching to form the contact hole CH. At this time, etching is performed until at least the second cladding layer 102 is exposed (so that an etching bottom surface is located in the second cladding layer 102).

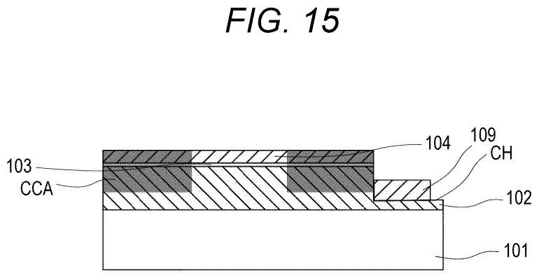

In the next step S4, the third electrode 109 is formed (see FIG. 15). Specifically, the third electrode 109 is formed in the contact hole CH so as to be in contact with the second cladding layer 102 by a lift-off method, for example.

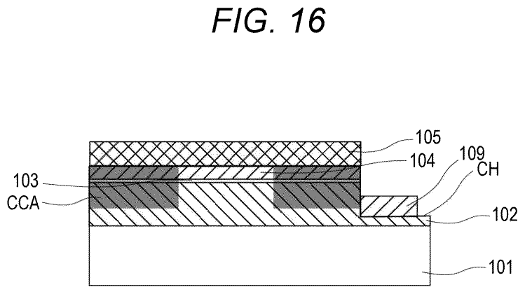

In the next step S5, the characteristic layer 105 is stacked on the stacked body (see FIG. 16). Specifically, a transparent conductive film as the characteristic layer 105 is formed so as to cover (overlap) the current confinement region CCA and the current passage region CPA of the stacked body.

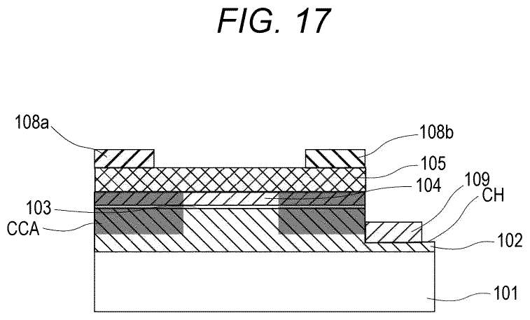

In the next step S6, the first and second electrodes 108a and 108b are formed (see FIG. 17). Specifically, the first and second electrodes 108a and 108b are formed so as to be apart from each other along the characteristic layer 105 by the lift-off method, for example.

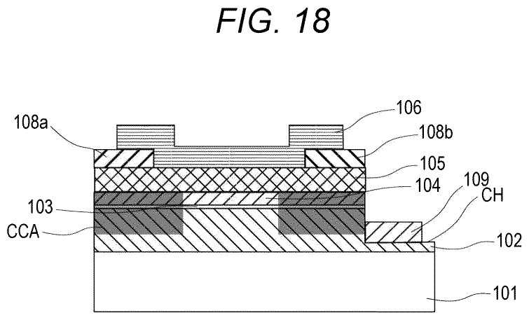

In the next step S7, the first reflector 106 is formed (see FIG. 18). Specifically, for example, two kinds of dielectric films (for example, a Ta₂O₅ layer and a SiO₂ layer) as materials of the first reflector 106 are alternately formed so as to straddle the characteristic layer 105 and the first and second electrodes 108a and 108b.

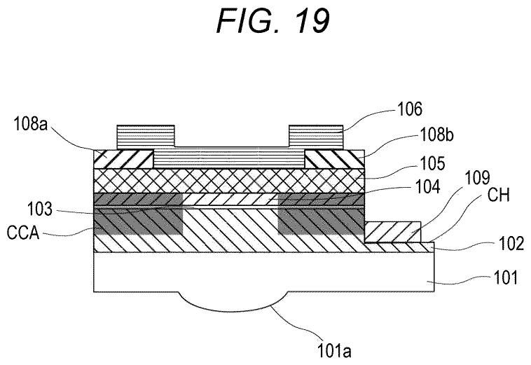

In the next step S8, the substrate 101 is etched to form a convex curved surface (see FIG. 19). Specifically, the back surface (lower surface) of the substrate 101 is dry-etched to form a convex curved surface 101a.

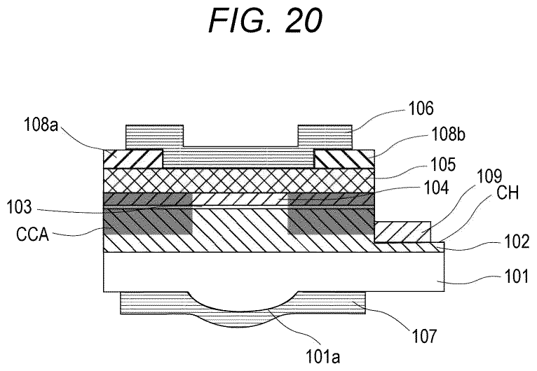

In the final step S9, the concave second reflector 107 is formed (see FIG. 20). Specifically, for example, two kinds of dielectric films (for example, a Ta₂O₅ layer and a SiO₂ layer) as materials of the second reflector 107 are alternately formed on the convex curved surface 101a.

(9) Effects of Surface Emitting Element and Method for Manufacturing the Same

The surface emitting element 100 according to the first embodiment of the present technology includes the light emitting layer 103, the characteristic layer 105 disposed on the optical path of light generated in the light emitting layer 103, the characteristic layer 105 exhibiting an electrical characteristic due to light incidence and/or having variability in an optical characteristic due to voltage application, and a plurality of (for example, two) electrodes (for example, the first and second electrodes 108a and 108b) provided on the characteristic layer 105.

In the surface emitting element 100, since the first and second electrodes 108a and 108b are provided on the characteristic layer 105, the electrical characteristic exhibited by the characteristic layer 105 on which the light generated in the light emitting layer 103 is incident can be directly detected.

In the surface emitting element 100, since the first and second electrodes 108a and 108b are provided on the characteristic layer 105, the optical characteristic of the light generated in the light emitting layer 103 and incident on the characteristic layer 105 can be adjusted by generating a potential difference between the first and second electrodes 108a and 108b to change the optical characteristic of the characteristic layer 105.

As a result, the surface emitting element 100 according to the first embodiment of the present technology can provide a surface emitting element capable of enabling highly accurate detection of an optical characteristic of an emitted light and enabling adjustment of the optical characteristic of the emitted light.

The light emitting layer 103 and the characteristic layer 105 are stacked on each other. Thus, as compared with a case where the light emitting layer and the characteristic layer are provided separately, there is no need for positioning or the like, and utility is higher.

Furthermore, the surface emitting element 100 can be manufactured by a semiconductor manufacturing method similarly to the method of manufacturing a surface emitting element having no light detecting function.

Furthermore, it is not necessary to provide an additional component such as a PD separately from the light emitting layer, and it is not necessary to perform a step of mounting the additional component.

In the surface emitting element 100, since an electrode and a transparent conductive film which are normally equipped in a surface emitting element having no light detecting function are used, it is possible to suppress an increase in size of the element.

The plurality of electrodes 108a and 108b is disposed apart from each other along the characteristic layer 105. As a result, the electrical characteristic (for example, electrical resistance) in the in-plane direction of the characteristic layer 105 on which light is incident can be accurately detected. Furthermore, since a potential difference can be generated in the in-plane direction of the characteristic layer 105 and carriers can be injected in a relatively wide range, the optical characteristic in a relatively wide range in the in-plane direction of the characteristic layer 105 can be changed, and furthermore, the optical characteristic (for example, the amount of light) of an entire region of a cross section of the light (emitted light) generated in the light emitting layer 103 and incident on the characteristic layer 105 can be adjusted.

The surface emitting element 100 further includes the first and second reflectors 106 and 107 disposed at positions sandwiching the light emitting layer 103, and the characteristic layer 105 is disposed between the first reflector 106 and the light emitting layer 103. That is, the characteristic layer 105 is disposed in the element (specifically, in the resonator R). As a result, no additional optical loss occurs. On the other hand, in a conventional technology (for example, Japanese Patent No. 4674642), light leaked outside the element is detected, and thus optical loss occurs.

The electrical characteristic described above can include, for example, a characteristic in which the electrical resistance changes in accordance with a change in the amount of incident light.

The changing of the optical characteristic described above can be, for example, that the light absorption end is shifted to the short wavelength side by voltage application.

The characteristic layer 105 can absorb, for example, a part of the incident light.

The characteristic layer 105 can include, for example, a transparent conductive film.

The light emitting layer 103 includes, for example, the light emitting region LA and the non-light emitting region NLA surrounding the light emitting region LA, and the plurality of electrodes 108a and 108b can include at least one first electrode 108a disposed at a position corresponding to a section on one side of both sides sandwiching the light emitting region LA in the non-light emitting region NLA and at least one second electrode 108b disposed at a position corresponding to a section on the other side.

The characteristic layer 105 is preferably disposed so as to overlap at least the position LEC having the highest light emission intensity in the in-plane direction of the light emitting region LA.

In the characteristic layer 105, the size (area) of a region corresponding to the light emitting region LA (for example, the central region 105a) is preferably smaller than the size of each of regions (for example, the first and second peripheral regions 105b1 and 105b2) corresponding to the sections NLA1 and NLA2 on both sides sandwiching the light emitting region LA of the non-light emitting region NLA in plan view.

In the characteristic layer 105, in plan view, in a region corresponding to the light emitting region LA (for example, the central region 105a), a width of a part corresponding to the position LEC having the highest light emission intensity in the in-plane direction of the light emitting region LA is preferably the narrowest.

At least one of the first or second electrode 108a or 108b can also serve as an electrode for supplying current to the light emitting layer 103.

A method for detecting an optical characteristic according to the first embodiment of the present technology (for example, the optical characteristic detection processing 1) is a method for detecting an optical characteristic of a light emitted from the surface emitting element 100 including the light emitting layer 103, the characteristic layer 105 that is disposed on an optical path of light generated in the light emitting layer 103 and exhibits an electrical characteristic due to light incidence, and a plurality of electrodes including the first electrode 108a and the second electrode 108b provided on the characteristic layer, the method including applying substantially the same potential to the first electrode 108a and the second electrode 108b to drive the surface emitting element 100, generating a potential difference between the first electrode 108a and the second electrode 108b by superimposing a potential on at least one of the first electrode 108a or the second electrode 108b while the surface emitting element 100 is being driven, and measuring the electrical characteristic of the characteristic layer 105.

As a result, the optical characteristic of the light emitted from the surface emitting element 100 can be detected with high accuracy.

A method for detecting an optical characteristic according to the first embodiment of the present technology (for example, the optical characteristic detection processing 2) is a method for detecting an optical characteristic of a light emitted from the surface emitting element 100 including the light emitting layer 103, the characteristic layer 105 that is disposed on an optical path of light generated in the light emitting layer 103 and exhibits an electrical characteristic due to light incidence, the plurality of electrodes including the first electrode 108a and the second electrode 108b provided on the characteristic layer 105, and the third electrode 109 disposed on a side opposite to the characteristic layer 105 of the light emitting layer 103, the method including applying substantially the same potential to the first electrode 108a and the second electrode 108b to drive the surface emitting element 100, turning off driving of the surface emitting element 100 and applying substantially the same potential to one of the first electrode 108a or the second electrode 108b and the third electrode 109, and measuring the electrical characteristic of the characteristic layer 105.

As a result, the optical characteristic of the light emitted from the surface emitting element 100 can be detected with high accuracy.

A method for adjusting an optical characteristic according to the first embodiment of the present technology (for example, the optical characteristic adjustment processing) is a method for adjusting an optical characteristic of a light emitted from the surface emitting element including the light emitting layer 103, the characteristic layer 105 that is disposed on an optical path of light generated in the light emitting layer 103 and has variability in an optical characteristic due to voltage application, the plurality of electrodes including the first electrode 108a and the second electrode 108b provided on the characteristic layer 105, and the third electrode 109 disposed on the side opposite to the characteristic layer 105 of the light emitting layer 103, the method including applying a potential to one of the first electrode 108a or the second electrode 108b to generate a potential difference between the first electrode 108a and the second electrode 108b, and applying a potential substantially the same as the potential to the third electrode 109 to inject carriers into the characteristic layer 105, and driving the surface emitting element 100 by generating a potential difference between at least one of the first electrode 108a or the second electrode 108b and the third electrode 109.

As a result, the optical characteristic of the light emitted from the surface emitting element 100 can be adjusted with high accuracy.

3. Surface Emitting Element According to Modifications 1 to 3 of First Embodiment of Present Technology

Hereinafter, surface emitting elements according to Modifications 1 to 3 of the first embodiment of the present technology will be described.

(Modification 1)

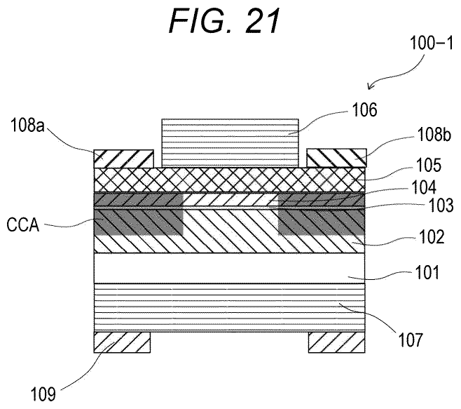

As shown in FIG. 21, a surface emitting element 100-1 according to Modification 1 has a configuration substantially similar to the configuration of the surface emitting element 100 according to the first embodiment except that the entire first reflector 106 is disposed between the first and second electrodes 108a and 108b and the third electrode 109 is provided in a circling shape (for example, annular shape) on the lower surface of the second reflector 107.

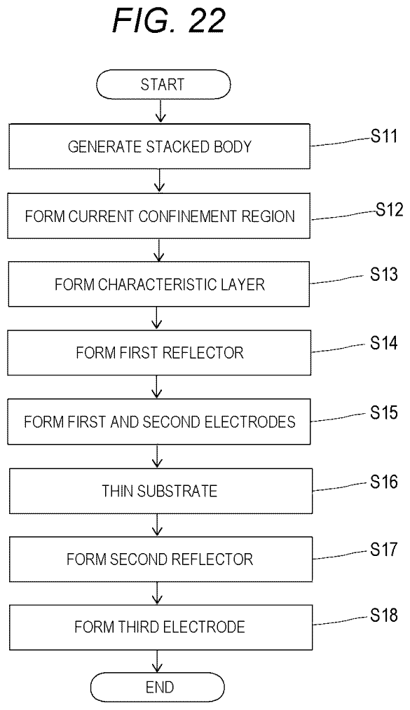

Hereinafter, an example of a method for manufacturing the surface emitting element 100-1 will be described with reference to the flowchart (steps S11 to S18) in FIG. 22. The surface emitting element 100-1 can also be manufactured by a semiconductor manufacturing method using a semiconductor manufacturing device, similarly to the surface emitting element 100 according to the first embodiment.

In the first step S11, the stacked body L1 is generated (see FIG. 12). Specifically, the second cladding layer 102, the light emitting layer 103, and the first cladding layer 104 are stacked (epitaxially grown) in this order on the substrate 101 (for example, a GaN substrate) in a growth chamber by a metal organic chemical vapor deposition method (MOCVD method) or a molecular beam epitaxy method (MBE method) to generate the stacked body L1.

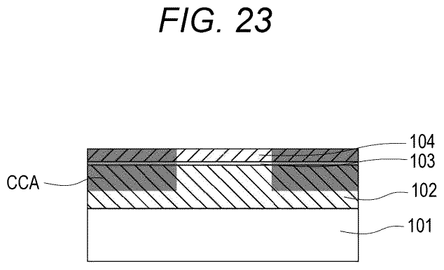

In the next step S12, the current confinement region CCA is formed (see FIG. 23). Specifically, a region where the current confinement region CCA of the stacked body is not formed (for example, a region to be the current passage region CPA) is protected by a protective film including resist, SiO₂, or the like, and ions (for example, B⁺⁺) are implanted from the side of the first cladding layer 104 into a circling region (for example, an annular region) of the stacked body not protected by the protective film. The depth of the ion implantation at this time is up to a part (the upper part) of the second cladding layer 102.

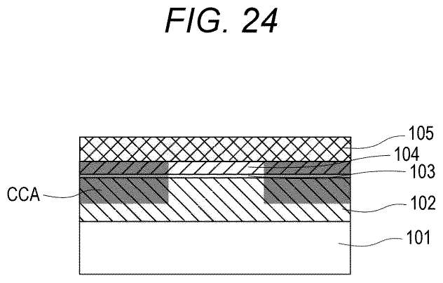

In the next step S13, the characteristic layer 105 is stacked on the stacked body (see FIG. 24). Specifically, a transparent conductive film as the characteristic layer 105 is formed so as to cover the current confinement region CCA and the current passage region CPA of the stacked body.

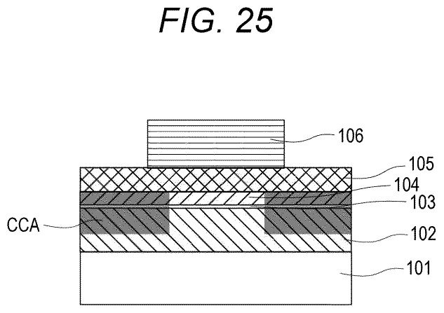

In the next step S14, the first reflector 106 is formed (see FIG. 25). Specifically, for example, two kinds of dielectric films (for example, a Ta₂O₅ layer and a SiO₂ layer) as materials of the first reflector 106 are alternately stacked on a central part of the characteristic layer 105.

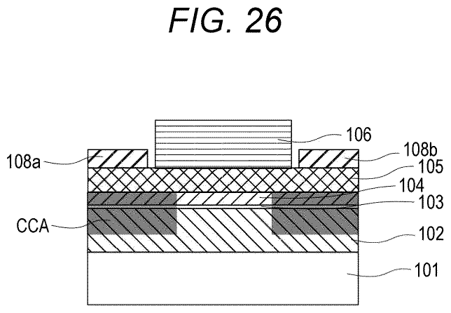

In the next step S15, the first and second electrodes 108a and 108b are formed (see FIG. 26). Specifically, the first and second electrodes 108a and 108b are formed at positions sandwiching the first reflector 106 by the lift-off method, for example.

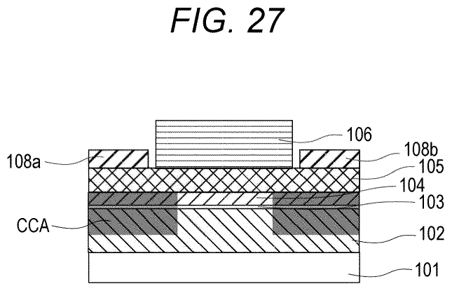

In the next step S16, the back surface (lower surface) of the substrate 101 is ground and thinned (see FIG. 27).

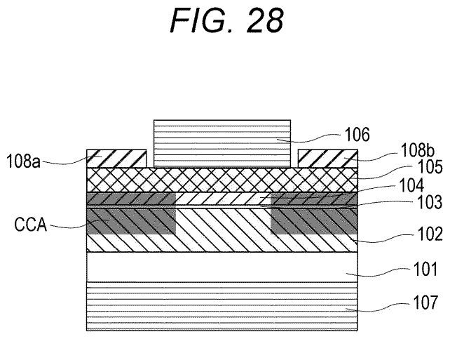

In the next step S17, the second reflector 107 is formed (see FIG. 28). Specifically, for example, two kinds of dielectric films (for example, a Ta₂O₅ layer and a SiO₂ layer) as materials of the second reflector 107 are alternately formed on the back surface of the substrate 101.

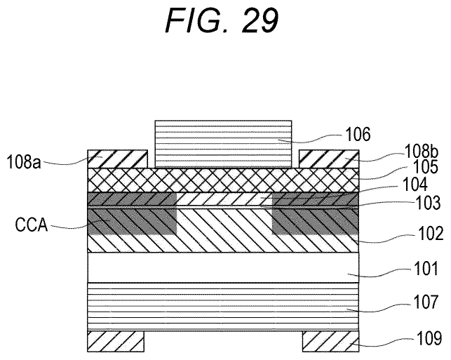

In the final step S18, the third electrode 109 is formed (see FIG. 29). Specifically, the third electrode 109 is formed in a circular shape (for example, an annular shape) on a back surface (lower surface) of the second reflector 107 by the lift-off method, for example.

The surface emitting element 100-1 described above also has an effect similar to the effect of the surface emitting element 100 according to the first embodiment. Similarly to the surface emitting element 100, the surface emitting element 100-1 can also be used for the optical characteristic detection processing 1 and 2 and the method for adjusting the optical characteristic described above.

(Modification 2)

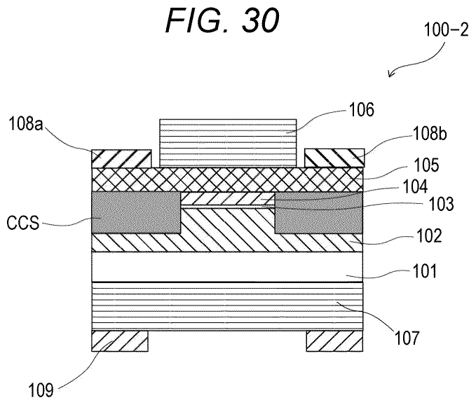

As shown in FIG. 30, a surface emitting element 100-2 according to Modification 2 has a configuration substantially similar to the configuration of the surface emitting element 100 according to the first embodiment except that the entire first reflector 106 is disposed between the first and second electrodes 108a and 108b, the third electrode 109 is provided in a circling shape (for example, annular shape) on the lower surface of the second reflector 107, and a current confinement structure CCS including, for example, benzocyclobutene (BCB) is provided instead of the current confinement region CCA.

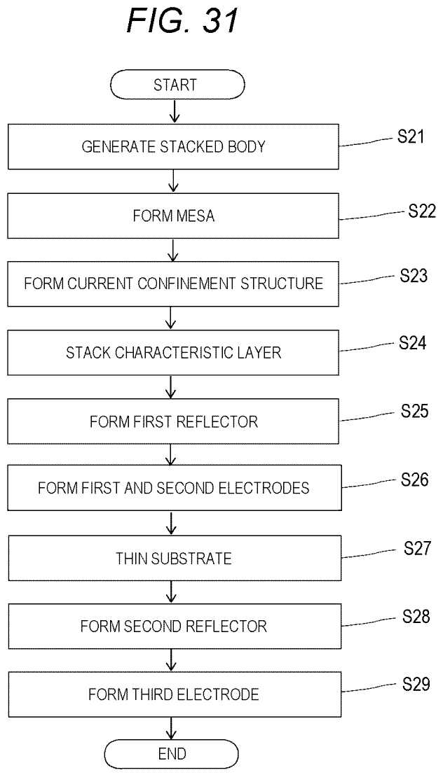

Hereinafter, an example of a method for manufacturing the surface emitting element 100-2 will be described with reference to the flowchart (steps S21 to S29) in FIG. 31. The surface emitting element 100-2 can also be manufactured by a semiconductor manufacturing method using a semiconductor manufacturing device, similarly to the surface emitting element 100 according to the first embodiment.

In the first step S21, the stacked body L1 is generated (see FIG. 12). Specifically, the second cladding layer 102, the light emitting layer 103, and the first cladding layer 104 are stacked (epitaxially grown) in this order on the substrate 101 (for example, a GaN substrate) in a growth chamber by a metal organic chemical vapor deposition method (MOCVD method) or a molecular beam epitaxy method (MBE method) to generate the stacked body L1.

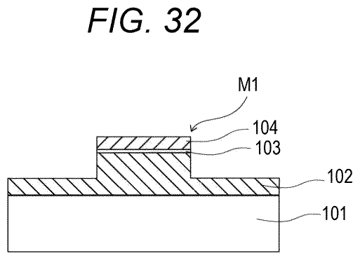

In the next step S22, a mesa M1 is formed (see FIG. 32). Specifically, first, a resist pattern is formed at a position where the mesa M1 is to be formed in the stacked body L1 (see FIG. 12). Next, by using this resist pattern as a mask, the stacked body L1 is etched by, for example, dry etching or wet etching to form the mesa M1. At this time, etching is performed until at least the second cladding layer 102 is reached (until the etching bottom surface is located in the second cladding layer 102).

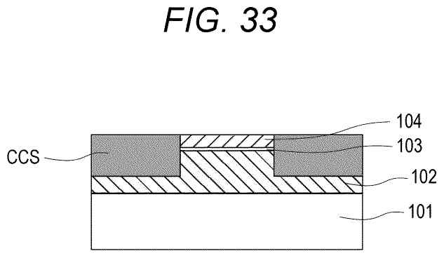

In the next step S23, the current confinement structure CCS is formed (see FIG. 33). Specifically, a periphery of the mesa M1 (see FIG. 32) is embedded with, for example, BCB to form the current confinement structure CCS surrounding the mesa M1 (see FIG. 32).

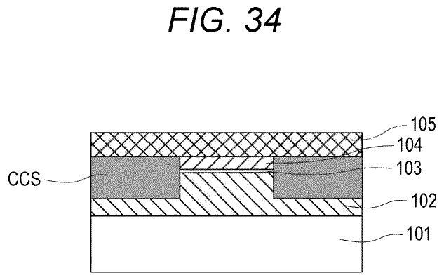

In the next step S24, the characteristic layer 105 is stacked (see FIG. 34). Specifically, a transparent conductive film as the characteristic layer 105 is formed so as to cover the mesa M1 (see FIG. 32) and the current confinement structure CCS.

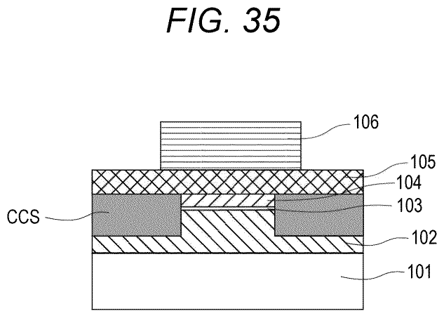

In the next step S25, the first reflector 106 is formed (see FIG. 35). Specifically, for example, two kinds of dielectric films (for example, a Ta₂O₅ layer and a SiO₂ layer) as materials of the first reflector 106 are alternately formed on the central part of the characteristic layer 105.

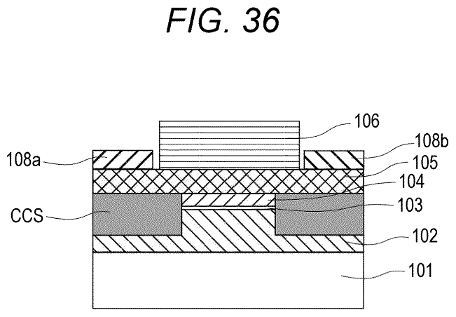

In the next step S26, the first and second electrodes 108a and 108b are formed (see FIG. 36). Specifically, the first and second electrodes 108a and 108b are formed at positions sandwiching the characteristic layer 105 by the lift-off method, for example.

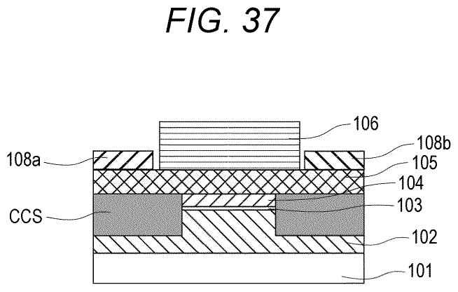

In the next step S27, the back surface (lower surface) of the substrate 101 is ground and thinned (see FIG. 37).

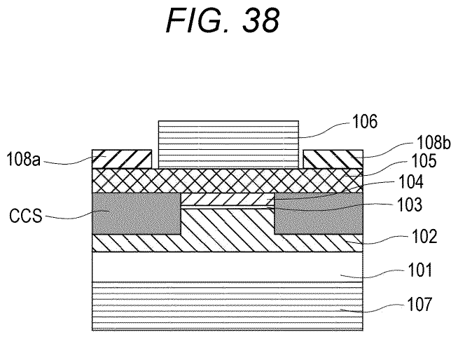

In the next step S28, the second reflector 107 is formed (see FIG. 38). Specifically, for example, two kinds of dielectric films (for example, a Ta₂O₅ layer and a SiO₂ layer) as materials of the second reflector 107 are alternately formed on the back surface of the substrate 101.

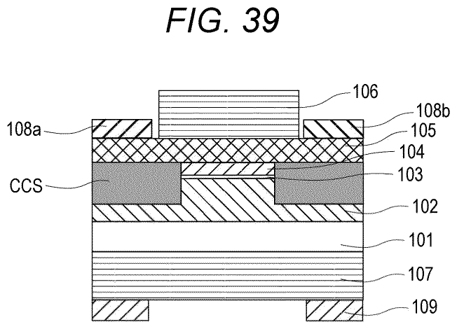

In the final step S29, the third electrode 109 is formed (see FIG. 39). Specifically, the third electrode 109 is formed in a circular shape (for example, an annular shape) on a back surface (lower surface) of the second reflector 107 by the lift-off method, for example.

The surface emitting element 100-2 described above also has an effect similar to the effect of the surface emitting element 100 according to the first embodiment. Similarly to the surface emitting element 100, the surface emitting element 100-2 can also be used for the optical characteristic detection processing 1 and 2 and the optical characteristic adjustment processing described above.

(Modification 3)

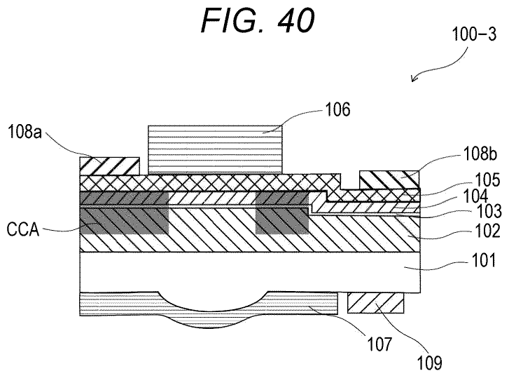

In a surface emitting element 100-3 according to Modification 2, as shown in FIG. 40, the characteristic layer 105 has a level difference, the first electrode 108a is provided on an upper step of the characteristic layer 105, and the second electrode 108b is provided on a lower step of the characteristic layer 105. That is, in the surface emitting element 100-2, the first and second electrodes 108a and 108b are not on the same plane.

The surface emitting element 100-3 can be manufactured by a manufacturing method similar to the method for manufacturing the surface emitting element 100 according to the first embodiment except that when the stacked body L1 is generated, a level difference is formed on the second cladding layer 102 by, for example, etching after the second cladding layer 102 is stacked, the light emitting layer 103, the first cladding layer 104, and the characteristic layer 105 are stacked on the second cladding layer 102, and the third electrode 109 is formed beside the second reflector 107 on the back surface of the substrate 101.

The surface emitting element 100-3 also has an effect similar to the effect of the surface emitting element 100 according to the first embodiment. Similarly to the surface emitting element 100, the surface emitting element 100-3 can also be used for the optical characteristic detection processing 1 and 2 and the optical characteristic adjustment processing described above.

4. Surface Emitting Element According to Second Embodiment of Present Technology

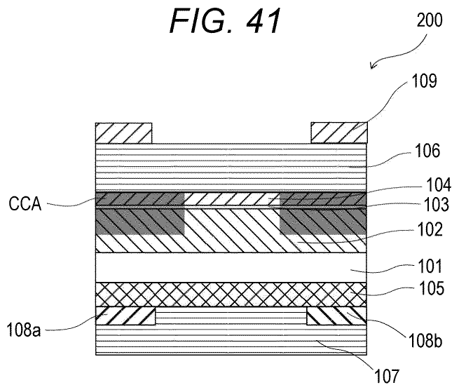

As shown in FIG. 41, a surface emitting element 200 according to a second embodiment of the present technology has a configuration similar to the configuration of the surface emitting element 100-1 (see FIG. 21) according to Modification 1 of the first embodiment except that the characteristic layer 105 and the first and second electrodes 108a and 108b are provided between the substrate 101 and the second reflector 107. Specifically, in the surface emitting element 200, the first and second electrodes 108a and 108b are disposed between the characteristic layer 105 and the second reflector 107.

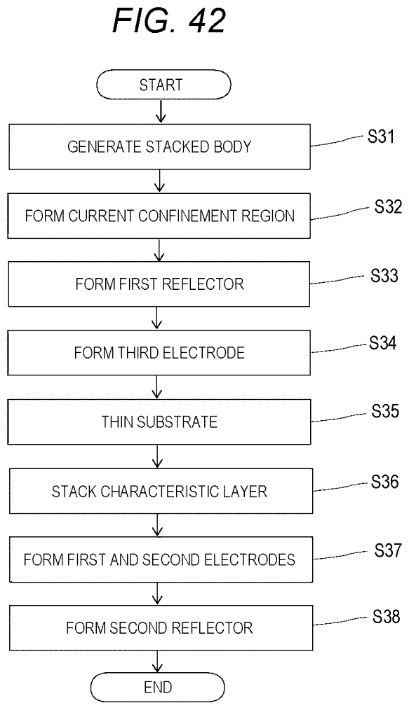

Hereinafter, an example of a method for manufacturing the surface emitting element 200 will be described with reference to the flowchart (steps S31 to S38) in FIG. 42. The surface emitting element 200 can also be manufactured by a semiconductor manufacturing method using a semiconductor manufacturing device, similarly to the surface emitting element 100-1 according to Modification 1 of the first embodiment.

In the first step S31, the stacked body L1 is generated (see FIG. 12). Specifically, the second cladding layer 102, the light emitting layer 103, and the first cladding layer 104 are stacked (epitaxially grown) in this order on the substrate 101 (for example, a GaN substrate) in a growth chamber by a metal organic chemical vapor deposition method (MOCVD method) or a molecular beam epitaxy method (MBE method) to generate the stacked body L1.

In the next step S32, the current confinement region CCA is formed (see FIG. 23). Specifically, a region where the current confinement region CCA of the stacked body is not formed (described later) (for example, a region to be the current passage region CPA) is protected by a protective film including resist, SiO₂, or the like, and ions (for example, B⁺⁺) are implanted from the side of the first cladding layer 104 into a circling region (for example, an annular region) of the stacked body L1 not protected by the protective film. The depth of the ion implantation at this time is up to a part (the upper part) of the second cladding layer 102.

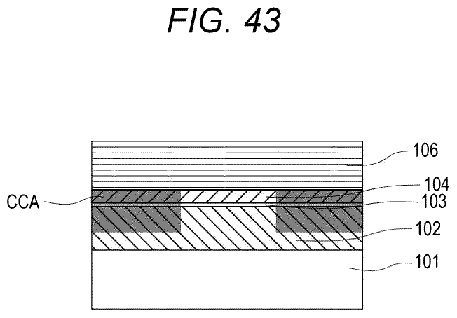

In the next step S33, the first reflector 106 is formed (see FIG. 43). Specifically, for example, two kinds of dielectric films (for example, a Ta₂O₅ layer and a SiO₂ layer) as materials of the first reflector 106 are alternately formed on the central part of the characteristic layer 105.

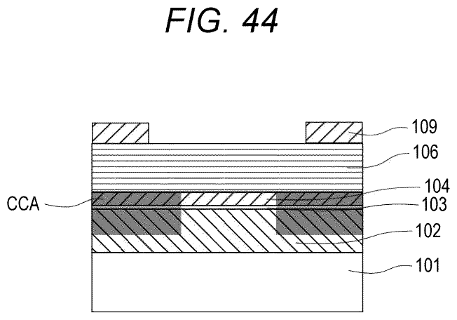

In the next step S34, the third electrode 109 is formed (see FIG. 44). Specifically, the third electrode 109 is formed in a circular shape (for example, an annular shape) on a front surface (upper surface) of the first reflector 106 by the lift-off method, for example.

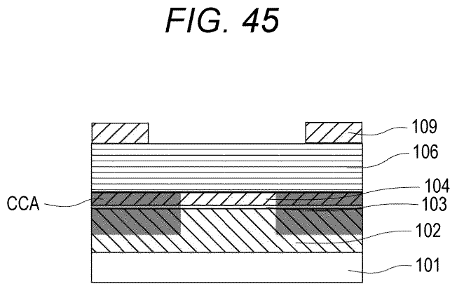

In the next step S35, the back surface (lower surface) of the substrate 101 is ground and thinned (see FIG. 45).

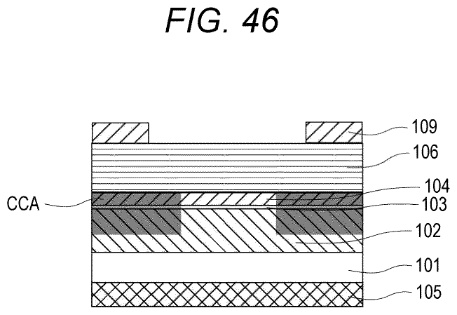

In the next step S36, the characteristic layer 105 is formed on the back surface (lower surface) of the substrate 101 (see FIG. 46). Specifically, a transparent conductive film as the characteristic layer 105 is formed on the back surface of the substrate 101 so as to overlap the current confinement region CCA and the current passage region CPA.

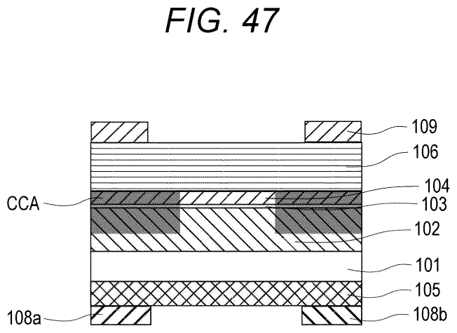

In the next step S37, the first and second electrodes 108a and 108b are formed (see FIG. 47). Specifically, the first and second electrodes 108a and 108b are formed so as to be apart from each other along the characteristic layer 105 by the lift-off method, for example.

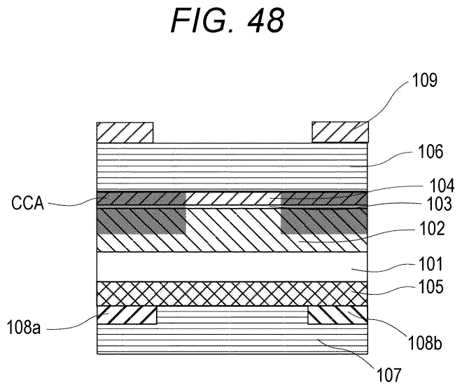

In the next step S38, the second reflector 107 is formed (see FIG. 48). Specifically, for example, two kinds of dielectric films (for example, a Ta₂O₅ layer and a SiO₂ layer) as materials of the second reflector 107 are alternately formed on the back surface (lower surface) of the characteristic layer 105 and the first and second electrodes 108a and 108b.

The surface emitting element 200 described above also has an effect similar to the effect of the surface emitting element 100 according to the first embodiment. Similarly to the surface emitting element 100, the surface emitting element 200 can also be used for the optical characteristic detection processing 1 and 2 and the optical characteristic adjustment processing described above.

5. Surface Emitting Element According to Modifications 1 and 2 of Second Embodiment of Present Technology

Hereinafter, surface emitting elements according to Modifications 1 and 2 of the second embodiment of the present technology will be described.

(Modification 1)

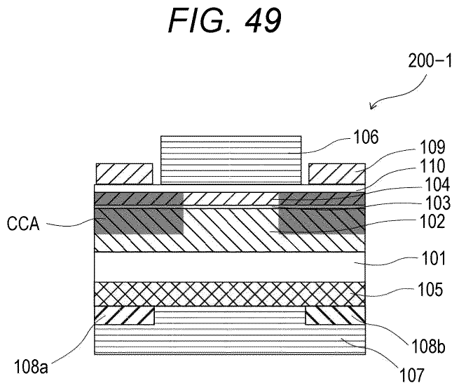

As shown in FIG. 49, a surface emitting element 200-1 according to Modification 1 has a configuration similar to the configuration of the surface emitting element 200 according to the second embodiment except that a contact layer 110 is disposed between the first cladding layer 104 and the first reflector 106, and the third electrode 109 is provided on the contact layer 110 in a circling shape (for example, annular shape) so as to surround the first reflector 106. That is, in the surface emitting element 200-1, the contact layer 110 is disposed so as to cover the current confinement region CCA and the current passage region CPA, and the first and second electrodes 108a and 108b are provided on the contact layer 110. The contact layer 110 includes, for example, a GaN-based compound semiconductor.

The surface emitting element 200-1 also has an effect similar to the effect of the surface emitting element 100 according to the first embodiment. Similarly to the surface emitting element 100, the surface emitting element 200-1 can also be used for the optical characteristic detection processing 1 and 2 and the optical characteristic adjustment processing described above.

(Modification 2)

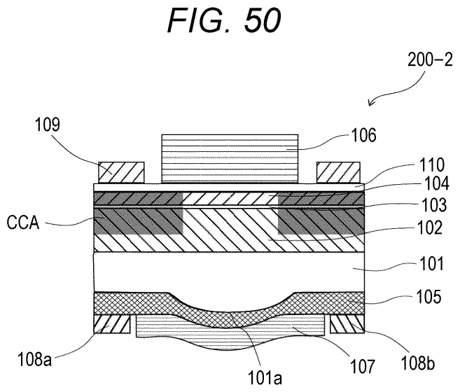

As shown in FIG. 50, a surface emitting element 200-2 according to Modification 2 has a configuration similar to the configuration of the surface emitting element 200-1 according to Modification 1 except that the characteristic layer 105 and the second reflector 107 are stacked in this order from a side of the substrate 101 along the convex curved surface 101a formed on the substrate 101, and the first and second electrodes 108a and 108b are disposed at positions sandwiching the second reflector 107 on the lower surface of the characteristic layer 105.

The surface emitting element 200-2 also has an effect similar to the effect of the surface emitting element 100 according to the first embodiment. Similarly to the surface emitting element 100, the surface emitting element 200-2 can also be used for the optical characteristic detection processing 1 and 2 and the optical characteristic adjustment processing described above.

6. Surface Emitting Element According to Third Embodiment of Present Technology

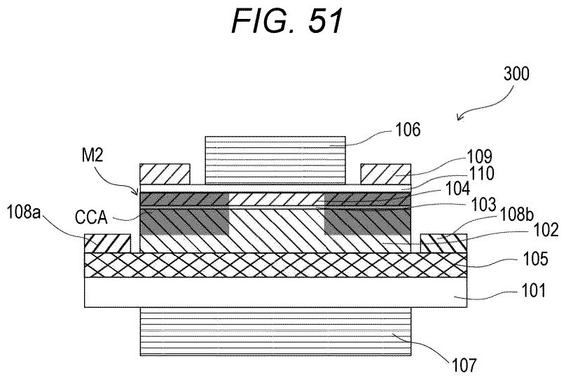

As shown in FIG. 51, a surface emitting element 300 according to a third embodiment of the present technology has a configuration substantially similar to the configuration of the surface emitting element 200-1 according to Modification 1 of the second embodiment except that the characteristic layer 105 is provided between the substrate 101 and the second cladding layer 102.

In the surface emitting element 300, a mesa M2 including the second cladding layer 102, the light emitting layer 103, and the first cladding layer 104 is formed on the characteristic layer 105. The first and second electrodes 108a and 108b are provided on a part of the characteristic layer 105 around the mesa M2.

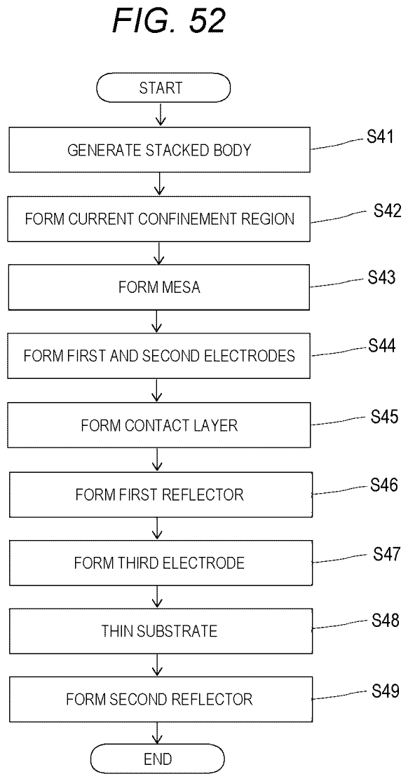

Hereinafter, an example of a method for manufacturing the surface emitting element 300 will be described with reference to the flowchart (steps S41 to S49) in FIG. 52. The surface emitting element 300 can also be manufactured by a semiconductor manufacturing method using a semiconductor manufacturing device, similarly to the surface emitting element 200-1 according to Modification 1 of the second embodiment.

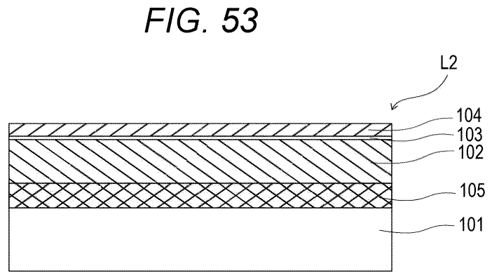

In the first step S41, a stacked body L2 is generated (see FIG. 53). Specifically, the characteristic layer 105, the second cladding layer 102, the light emitting layer 103, and the first cladding layer 104 are stacked (epitaxially grown) in this order on the substrate 101 (for example, a GaN substrate) in a growth chamber by the metal organic chemical vapor deposition method (MOCVD method) or the molecular beam epitaxy method (MBE method) to generate the stacked body L2.

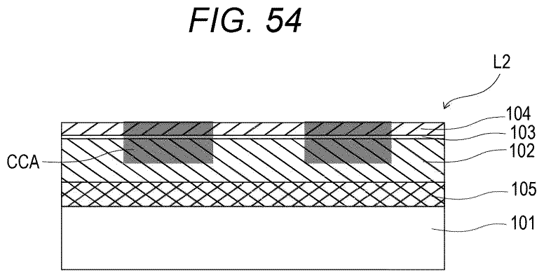

In the next step S42, the current confinement region CCA is formed (see FIG. 54). Specifically, a region where the current confinement region CCA of the stacked body is not formed (for example, a region to be the current passage region CPA) is protected by a protective film including resist, SiO₂, or the like, and ions (for example, B⁺⁺) are implanted from the side of the first cladding layer 104 into a circling region (for example, an annular region) of the stacked body L2 not protected by the protective film. The depth of the ion implantation at this time is up to a part (the upper part) of the second cladding layer 102.

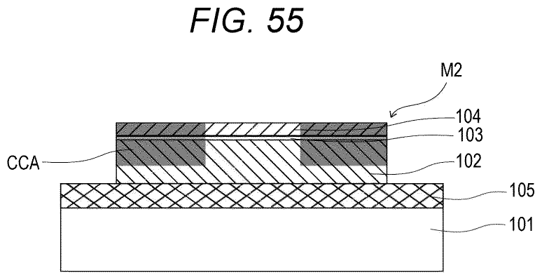

In the next step S43, the mesa M2 is formed (see FIG. 55). Specifically, first, a resist pattern is formed at a position where the mesa M2 is to be formed in the stacked body L2 (see FIG. 54). Next, by using this resist pattern as a mask, the stacked body L2 is etched by, for example, dry etching or wet etching to form the mesa M2. At this time, the etching is performed until the characteristic layer 105 is exposed (until a side surface of the second cladding layer 102 is completely exposed).

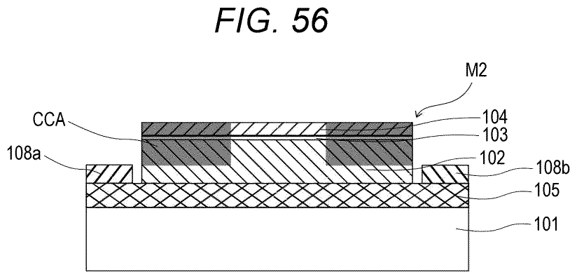

In the next step S44, the first and second electrodes 108a and 108b are formed (see FIG. 56). Specifically, the first and second electrodes 108a and 108b are formed at positions sandwiching the mesa M2 on the characteristic layer 105 by the lift-off method, for example.

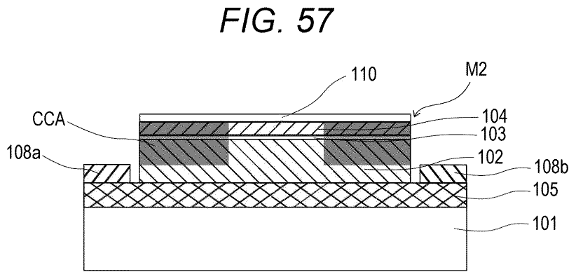

In the next step S45, the contact layer 110 is formed (see FIG. 57). Specifically, the contact layer 110 including, for example, a GaN-based compound semiconductor is formed on the mesa M2.

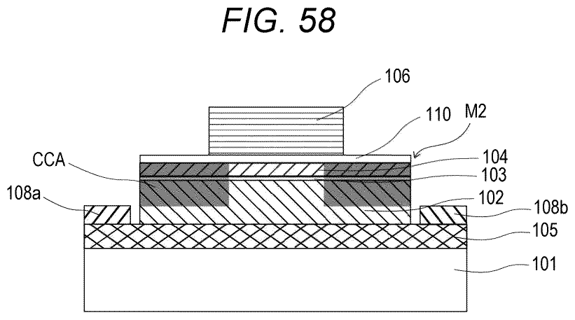

In the next step S46, the first reflector 106 is formed (see FIG. 58). Specifically, for example, two kinds of dielectric films (for example, a Ta₂O₅ layer and a SiO₂ layer) as materials of the first reflector 106 are alternately formed on a central part of the contact layer 110.

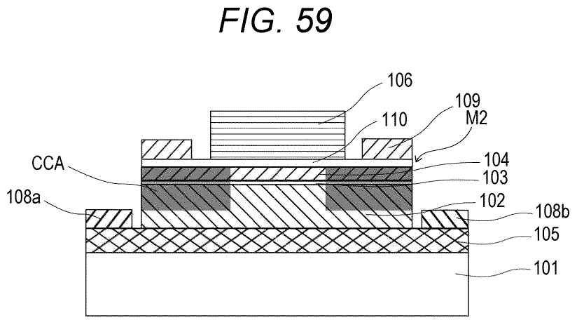

In the next step S47, the third electrode 109 is formed (see FIG. 59). Specifically, the third electrode 109 is formed in a circular shape (for example, an annular shape) on the contact layer 105 so as to surround the first reflector 106 by the lift-off method, for example.

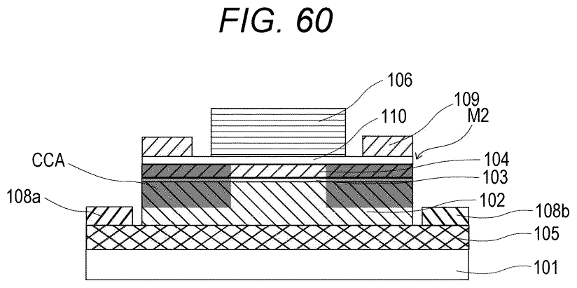

In the next step S48, the back surface (lower surface) of the substrate 101 is ground and thinned (see FIG. 60).

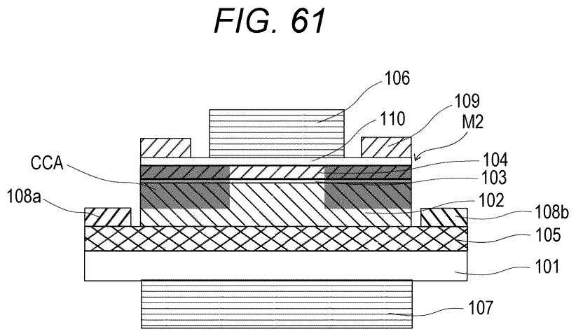

In the next step S49, the second reflector 107 is formed (see FIG. 61). Specifically, for example, two kinds of dielectric films (for example, a Ta₂O₅ layer and a SiO₂ layer) as materials of the second reflector 107 are alternately formed on the back surface of the substrate 101.

The surface emitting element 300 described above also has an effect similar to the effect of the surface emitting element 100 according to the first embodiment. Similarly to the surface emitting element 100, the surface emitting element 300 can also be used for the optical characteristic detection processing 1 and 2 and the optical characteristic adjustment processing described above.

7. Surface Emitting Element According to Modification of Third Embodiment of Present Technology

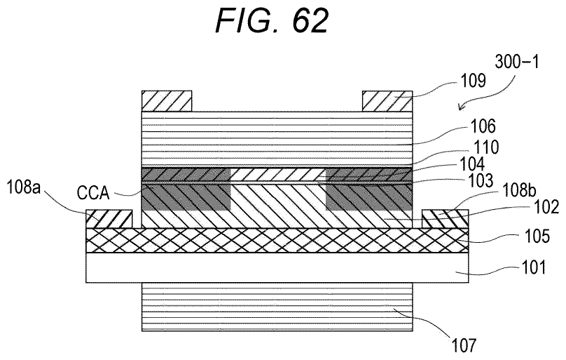

As shown in FIG. 62, a surface emitting element 300-1 according to the third embodiment of the present technology has a configuration similar to the configuration of the surface emitting element 300 according to the third embodiment except that the first reflector 106 is provided on an upper surface of the first cladding layer 104 and the third electrode 109 is provided on an upper surface of the first reflector 106. That is, the surface emitting element 300-1 does not include the contact layer 110 (see FIG. 51).

The surface emitting element 300-1 also has an effect similar to the effect of the surface emitting element 100 according to the first embodiment. Similarly to the surface emitting element 100, the surface emitting element 300-1 can also be used for the optical characteristic detection processing 1 and 2 and the optical characteristic adjustment processing described above.

8. Surface Emitting Element According to Fourth Embodiment of Present Technology

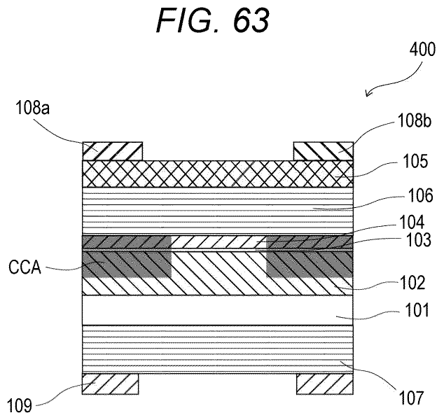

Hereinafter, as shown in FIG. 63, a surface emitting element 400 according to a fourth embodiment of the present technology has a configuration substantially similar to the configuration of the surface emitting element 200 (see FIG. 41) according to the second embodiment except that the characteristic layer 105 is provided on the first reflector 106 and the first and second electrodes 108a and 108b are provided on the characteristic layer 105.

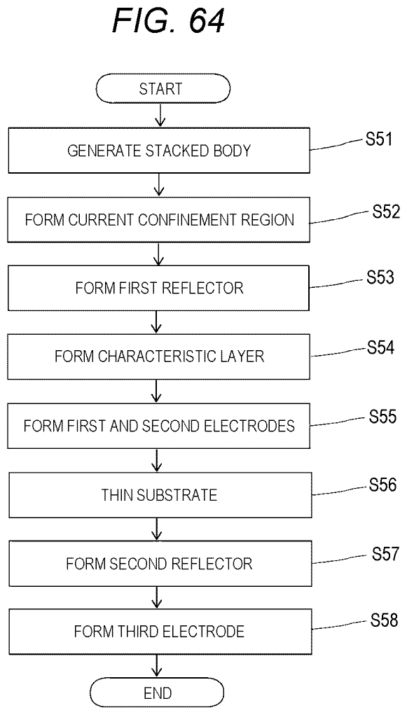

Hereinafter, an example of a method for manufacturing the surface emitting element 400 will be described with reference to the flowchart (steps S51 to S58) in FIG. 64. The surface emitting element 400 can also be manufactured by a semiconductor manufacturing method using a semiconductor manufacturing device, similarly to the surface emitting element 200 according to the second embodiment.

In the first step S51, the stacked body L1 is generated (see FIG. 12). Specifically, the second cladding layer 102, the light emitting layer 103, and the first cladding layer 104 are stacked (epitaxially grown) in this order on the substrate 101 (for example, a GaN substrate) in a growth chamber by a metal organic chemical vapor deposition method (MOCVD method) or a molecular beam epitaxy method (MBE method) to generate the stacked body L1.

In the next step S52, the current confinement region CCA is formed (see FIG. 23). Specifically, a region where the current confinement region CCA of the stacked body is not formed (for example, a region to be the current passage region CPA) is protected by a protective film including resist, SiO₂, or the like, and ions (for example, B⁺⁺) are implanted from the side of the first cladding layer 104 into a circling region (for example, an annular region) of the stacked body L1 not protected by the protective film. The depth of the ion implantation at this time is up to a part (the upper part) of the second cladding layer 102.

In the next step S53, the first reflector 106 is formed (see FIG. 43). Specifically, for example, two kinds of dielectric films (for example, a Ta₂O₅ layer and a SiO₂ layer) as materials of the first reflector 106 are alternately formed on the stacked body.

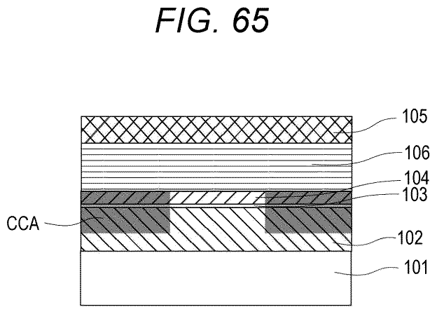

In the next step S54, the characteristic layer 105 is stacked (see FIG. 65). Specifically, a transparent conductive film as the characteristic layer 105 is formed on the first reflector 106 so as to overlap the current confinement region CCA and the current passage region CPA.

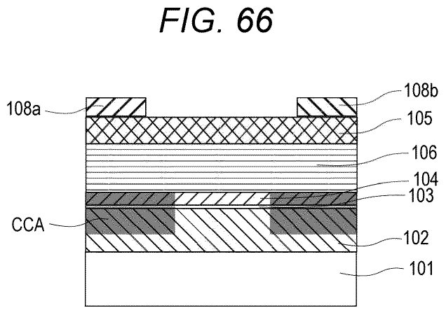

In the next step S55, the first and second electrodes 108a and 108b are formed (see FIG. 66). Specifically, the first and second electrodes 108a and 108b are formed on the characteristic layer 105 so as to be apart from each other along the characteristic layer 105 by the lift-off method, for example.

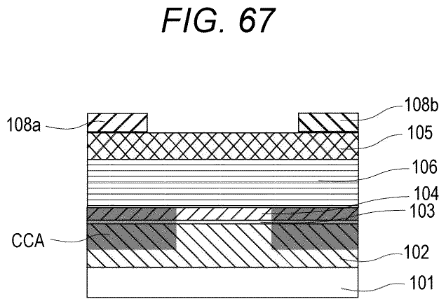

In the next step S56, the back surface (lower surface) of the substrate 101 is ground and thinned (see FIG. 67).

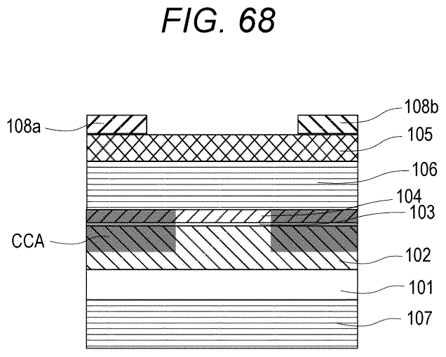

In the next step S57, the second reflector 107 is formed (see FIG. 68). Specifically, for example, two kinds of dielectric films (for example, a Ta₂O₅ layer and a SiO₂ layer) as materials of the second reflector 107 are alternately formed on the back surface (lower surface) of the substrate 101.

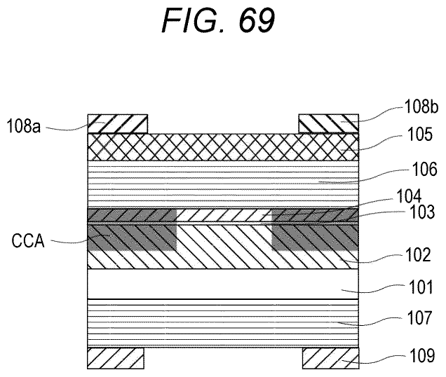

In the next step S58, the third electrode 109 is formed (see FIG. 69). Specifically, the third electrode 109 is formed in a circular shape (for example, an annular shape) on a back surface (lower surface) of the second reflector 107 by the lift-off method, for example.

The surface emitting element 400 described above also has an effect similar to the effect of the surface emitting element 100 according to the first embodiment. Similarly to the surface emitting element 100, the surface emitting element 400 can also be used for the optical characteristic detection processing 1 and 2 and the optical characteristic adjustment processing described above.

9. Surface Emitting Element According to Fifth Embodiment of Present Technology

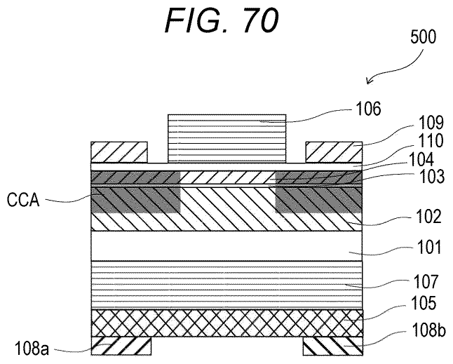

Hereinafter, as shown in FIG. 70, a surface emitting element 500 according to a fifth embodiment of the present technology has a configuration substantially similar to the configuration of the surface emitting element 200-1 (see FIG. 49) according to Modification 1 of the second embodiment except that the characteristic layer 105 is provided on the back surface (lower surface) of the second reflector 107 and the first and second electrodes 108a and 108b are provided on the back surface (lower surface) of the characteristic layer 105.

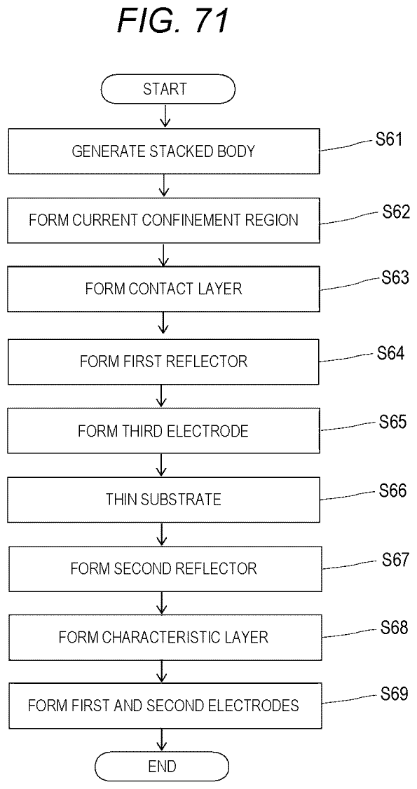

Hereinafter, an example of a method for manufacturing the surface emitting element 500 will be described with reference to the flowchart (steps S61 to S69) in FIG. 71. The surface emitting element 500 can also be manufactured by a semiconductor manufacturing method using a semiconductor manufacturing device, similarly to the surface emitting element 200-1 according to Modification 1 of the second embodiment.

In the first step S61, the stacked body L1 is generated (see FIG. 12). Specifically, the second cladding layer 102, the light emitting layer 103, and the first cladding layer 104 are stacked (epitaxially grown) in this order on the substrate 101 (for example, a GaN substrate) in a growth chamber by a metal organic chemical vapor deposition method (MOCVD method) or a molecular beam epitaxy method (MBE method) to generate the stacked body L1.

In the next step S62, the current confinement region CCA is formed (see FIG. 23). Specifically, a region where the current confinement region CCA of the stacked body is not formed (described later) (for example, a region to be the current passage region CPA) is protected by a protective film including resist, SiO₂, or the like, and ions (B⁺⁺) are implanted from the side of the first cladding layer 104 into a circling region (for example, an annular region) of the stacked body L1 not protected by the protective film. The depth of the ion implantation at this time is up to a part (the upper part) of the second cladding layer 102.

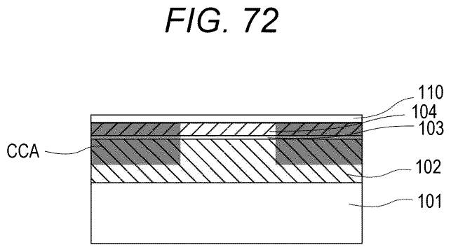

In the next step S63, the contact layer 110 is formed (see FIG. 72). Specifically, the contact layer 110 including a GaN-based compound is formed so as to cover the current confinement region CCA and the current passage region CPA.

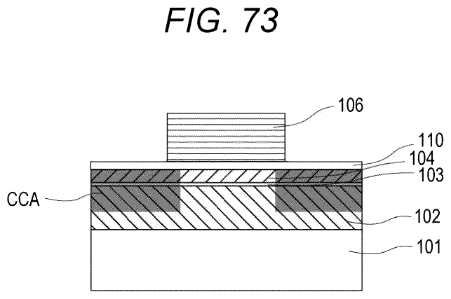

In the next step S64, the first reflector 106 is formed (see FIG. 73). Specifically, for example, two kinds of dielectric films (for example, a Ta₂O₅ layer and a SiO₂ layer) as materials of the first reflector 106 are alternately formed on a central part of the contact layer 110.

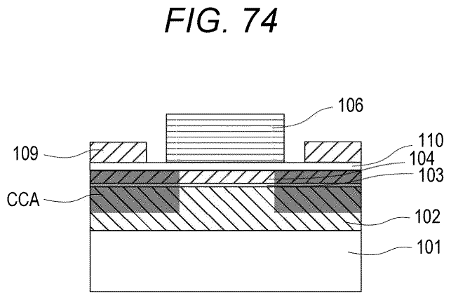

In the next step S65, the third electrode 109 is formed (see FIG. 74). Specifically, the third electrode 109 is formed in a circular shape (for example, an annular shape) on the contact layer 110 so as to surround the first reflector 106 by the lift-off method, for example.

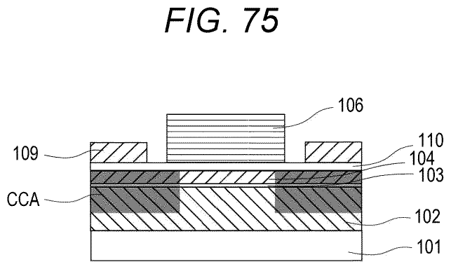

In the next step S66, the back surface (lower surface) of the substrate 101 is ground and thinned (see FIG. 75).

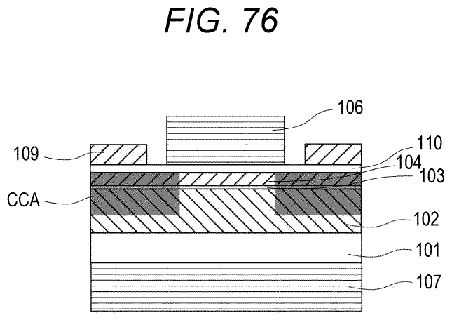

In the next step S67, the second reflector 107 is formed (see FIG. 76). Specifically, for example, two kinds of dielectric films (for example, a Ta₂O₅ layer and a SiO₂ layer) as materials of the second reflector 107 are alternately formed on the back surface (lower surface) of the substrate 101.

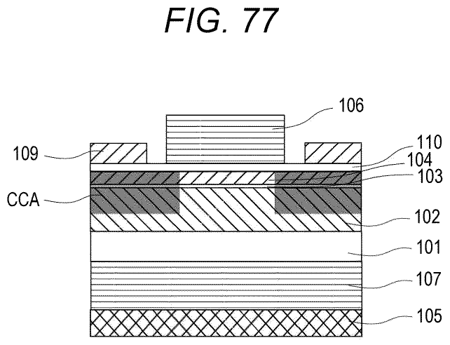

In the next step S68, the characteristic layer 105 is formed (see FIG. 77). Specifically, a transparent conductive film as the characteristic layer 105 is formed on the back surface (lower surface) of the second reflector 107 so as to overlap the current confinement region CCA and the current passage region CPA.

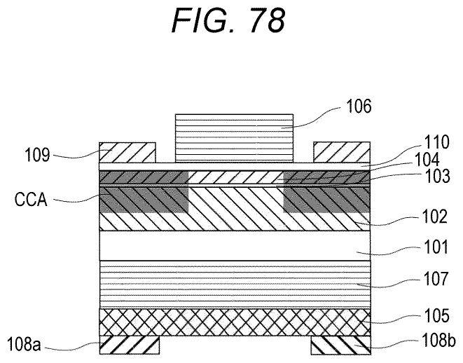

In the next step S69, the first and second electrodes 108a and 108b are formed (see FIG. 78). Specifically, the first and second electrodes 108a and 108b are formed on the back surface (lower surface) of the characteristic layer 105 so as to be apart from each other along the characteristic layer 105 by the lift-off method, for example.

The surface emitting element 500 described above also has an effect similar to the effect of the surface emitting element 100 according to the first embodiment. Similarly to the surface emitting element 100, the surface emitting element 500 can also be used for the optical characteristic detection processing 1 and 2 and the optical characteristic adjustment processing described above.

10. Surface Emitting Element According to Modifications 1 and 2 of Fifth Embodiment of Present Technology

Hereinafter, surface emitting elements according to Modifications 1 and 2 of the fifth embodiment of the present technology will be described.

(Modification 1)

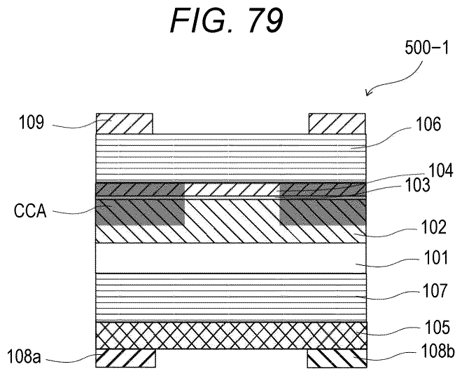

As shown in FIG. 79, a surface emitting element 500-1 according to Modification 1 of the fifth embodiment of the present technology has a configuration substantially similar to the configuration of the surface emitting element 500 (see FIG. 70) according to the fifth embodiment except that the first reflector 106 is provided on the first cladding layer 104 and the third electrode 109 is provided on the first reflector 106.

The surface emitting element 500-1 also has an effect similar to the effect of the surface emitting element 100 according to the first embodiment. Similarly to the surface emitting element 100, the surface emitting element 500-1 can also be used for the optical characteristic detection processing 1 and 2 and the optical characteristic adjustment processing described above.

(Modification 2)

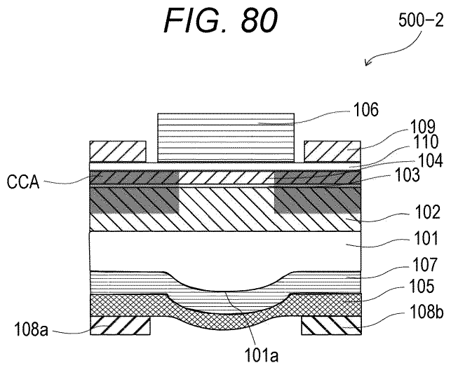

As shown in FIG. 80, a surface emitting element 500-2 according to Modification 2 of the fifth embodiment of the present technology has a configuration substantially similar to the configuration of the surface emitting element 500 according to the fifth embodiment except that the second reflector 107 is formed on the convex curved surface 101a formed on the back surface (lower surface) of the substrate 101 and the characteristic layer 105 is formed on the back surface (lower surface) of the second reflector 107.

The surface emitting element 500-2 also has an effect similar to the effect of the surface emitting element 100 according to the first embodiment. Similarly to the surface emitting element 100, the surface emitting element 500-2 can also be used for the optical characteristic detection processing 1 and 2 and the optical characteristic adjustment processing described above.

11. Examples 1 to 4 of Characteristic Layer of Surface Emitting Element of Present Technology.

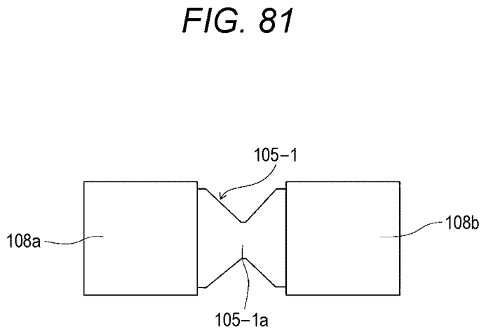

Hereinafter, Examples 1 to 4 of the characteristic layer of the surface emitting element of the present technology will be described with reference to FIGS. 81 to 84. Note that, in FIGS. 81 to 84, for convenience, only a region of the characteristic layer 105 located between the first and second electrodes 108a and 108b is illustrated in plan view.

In the transparent conductive film as the characteristic layer of each Example, the size of the region corresponding to the light emitting region located between the first and second electrodes 108a and 108b in plan view is smaller than the size of the region corresponding to the non-light emitting region on each of both sides sandwiching the light emitting region. That is, in the transparent conductive film as the characteristic layer of each Example, the electrical resistance of the region corresponding to the light emitting region is larger than the electrical resistance of the region corresponding to the non-light emitting region on each of both sides sandwiching the light emitting region. As a result, the detection sensitivity of the optical characteristic of the light generated in the light emitting layer and adjustability of the optical characteristic of the light generated in the light emitting layer can be enhanced.

### Example 1

As shown in FIG. 81, in the transparent conductive film as a characteristic layer 105-1 of Example 1, a region corresponding to the light emitting region located between the first and second electrodes 108a and 108b in plan view has a shape (shape in which electrical resistance increases) in which a width in a direction orthogonal to the arrangement direction of the first and second electrodes 108a and 108b in plan view becomes narrower as approaching a predetermined position (for example, intermediate position) between the first and second electrodes 108a and 108b.

Therefore, since a part (narrowest part) 105-1a having the narrowest width of the characteristic layer 105-1 is disposed so as to overlap the position having the highest light emission intensity in the in-plane direction of the light emitting region, the detection sensitivity of the optical characteristic of the light generated in the light emitting layer and the adjustability of the optical characteristic of the light generated in the light emitting layer can be enhanced as much as possible.

### Example 2

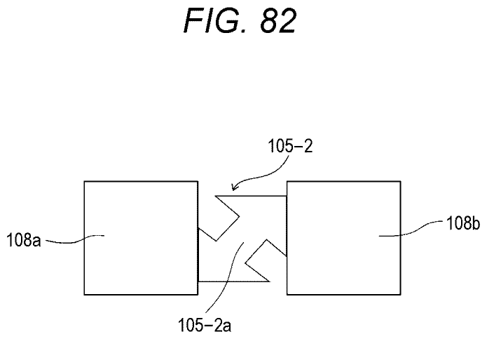

As shown in FIG. 82, in the transparent conductive film as a characteristic layer 105-2 of Example 2, a region corresponding to the light emitting region located between the first and second electrodes 108a and 108b in plan view has a two-way arrow shape facing a direction intersecting the arrangement direction of the first and second electrodes 108a and 108b in plan view. In the region corresponding to the light emitting region of the characteristic layer 105-2, an intermediate part 105-2a of the two-way arrow is smaller than both ends in plan view and has larger electrical resistance. Therefore, since the intermediate part 105-2a of the two-way arrow of the characteristic layer 105-2 is disposed so as to overlap the position having the highest light emission intensity in the in-plane direction of the light emitting region, the detection sensitivity of the optical characteristic of the light generated in the light emitting layer and the adjustability of the optical characteristic of the light generated in the light emitting layer can be enhanced as much as possible.

### Example 3

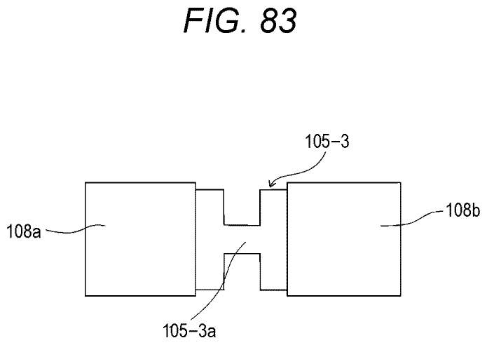

As shown in FIG. 83, in the transparent conductive film as a characteristic layer 105-3 of Example 3, a region corresponding to the light emitting region located between the first and second electrodes 108a and 108b in plan view has an H shape in which a horizontal line 105-3a is substantially parallel to the arrangement direction of the first and second electrodes 108a and 108b in plan view. In the region corresponding to the light emitting region of the characteristic layer 105-3, the H-shaped horizontal line 105-3a is smaller than each of two vertical lines on both sides of the horizontal line 105-3a and has a larger electrical resistance.

Therefore, since the horizontal part 105-3a of the characteristic layer 105-3 is disposed so as to overlap the position having the highest light emission intensity in the in-plane direction of the light emitting region, the detection sensitivity of the optical characteristic of the light generated in the light emitting layer and the adjustability of the optical characteristic of the light generated in the light emitting layer can be enhanced as much as possible.

### Example 4

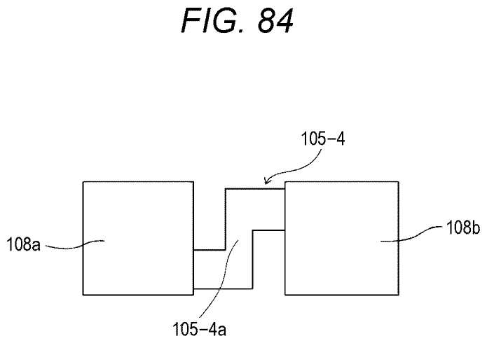

As shown in FIG. 84, in the transparent conductive film as a characteristic layer 105-4 of Example 4, a region corresponding to the light emitting region located between the first and second electrodes 108a and 108b in plan view has a crank shape in which one end is connected to the first electrode 108a and the other end is connected to the second electrode 108b in plan view. In the region corresponding to the light emitting region of the characteristic layer 105-4, an intermediate part 105-4a of the crank shape is smaller than both ends in plan view and has larger electrical resistance.

Therefore, since the intermediate part 105-4a of the characteristic layer 105-4 is disposed so as to overlap the position having the highest light emission intensity in the in-plane direction of the light emitting region, the detection sensitivity of the optical characteristic of the light (emitted light) generated in the light emitting layer and the adjustability of the optical characteristic of the light (emitted light) generated in the light emitting layer can be enhanced as much as possible.

The shape of the characteristic layer is not limited to the shapes illustrated in Example 1 to 4 described above, and can be appropriately changed.

12. Example of First and Second Electrodes and Examples 1 and 2 of First and Second Electrode Groups of Surface Emitting Element of Present Technology

Hereinafter, description will be made of Example of the first and second electrodes and Examples 1 and 2 of first and second electrode groups of the surface emitting element of the present technology

(Example of First and Second Electrodes)

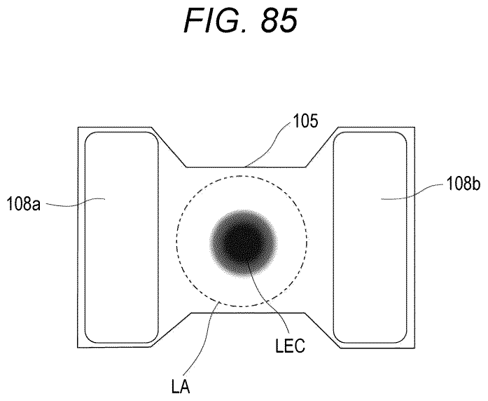

In the present example, as shown in FIG. 85, in plan view, the first electrode 108a is provided on a region on one side (a region corresponding to the non-light emitting region on one side) of both sides sandwiching the light emitting region LA of the characteristic layer 105 integrally configured as a whole, and the second electrode 108b is provided on a region on the other side (a region corresponding to the non-light emitting region on the other side).

In the present example, it is possible to detect the optical characteristic (for example, the amount) of the light (emitted light) generated in the light emitting layer and to adjust the optical characteristic (for example, the amount) of the light (emitted light) generated in the light emitting layer.

(Example 1 of First and Second Electrode Groups)

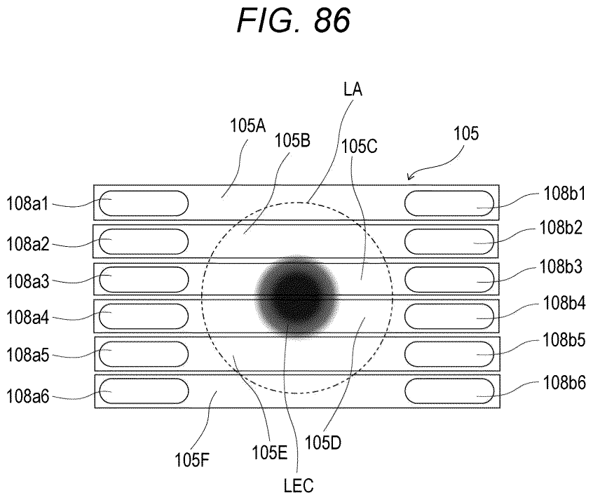

In Example 1, as shown in FIG. 86, the transparent conductive film as the characteristic layer 105 has a plurality of (for example, six) band-shaped regions (for example, first to sixth regions 105A to 105F) separated from each other.

The first to sixth regions 105A to 105F are disposed side by side in a direction substantially orthogonal to a longitudinal direction so that each of the regions overlaps a different part of the light emitting region LA in plan view.

First and second electrodes 108a1 and 108b1 constituting an electrode pair are provided at positions sandwiching the light emitting region LA of the first region 105A in plan view.

First and second electrodes 108a2 and 108b2 constituting an electrode pair are provided at positions sandwiching the light emitting region LA of the second region 105B in plan view.

First and second electrodes 108a3 and 108b3 constituting an electrode pair are provided at positions sandwiching the light emitting region LA of the third region 105C in plan view.

First and second electrodes 108a4 and 108b4 constituting an electrode pair are provided at positions sandwiching the light emitting region LA of the fourth region 105D in plan view.

First and second electrodes 108a5 and 108b5 constituting an electrode pair are provided at positions sandwiching the light emitting region LA of the fifth region 105E in plan view.

First and second electrodes 108a6 and 108b6 constituting an electrode pair are provided at positions sandwiching the light emitting region LA of the sixth region 105F in plan view.

Six first electrodes 108a1 to 108a6 disposed on one side of the light emitting region LA in plan view constitute a first electrode group.

Six second electrodes 108b1 to 108b6 disposed on the other side of the light emitting region LA in plan view constitute a second electrode group.

In Example 1, by applying a voltage to the electrode pair corresponding to each of the first to sixth regions 105A to 105F of the characteristic layer 105, it is possible to measure the electrical resistance of each of the regions, and eventually, for example, it is possible to estimate the lateral mode of the emitted light (intensity distribution in a cross section of the emitted light).

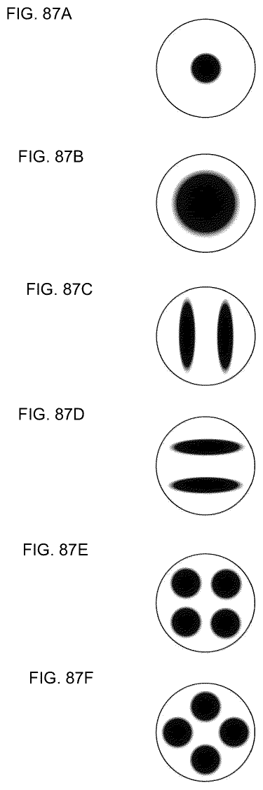

For example, in a case where the electrical resistance of the third and fourth regions 105C and 105D decreases, it can be estimated that the lateral mode is a single lateral mode with a relatively small substantially circular single intensity distribution as shown in FIG. 87A.

For example, in a case where the electrical resistance of the first to sixth regions 105A to 105F decreases, it can be estimated that the lateral mode is a single lateral mode having a relatively large substantially circular single intensity distribution as shown in FIG. 87B, a multiple lateral mode having a plurality of (for example, two) substantially elongated elliptical intensity distributions as shown in FIG. 87C, or a multiple lateral mode having a plurality of relatively small substantially circular intensity distributions (for example, four intensity distributions respectively located at four ends of a cross) as shown in FIG. 87F.

For example, in a case where the electrical resistance of the second and fifth regions 105B and 105E decreases, it can be estimated that the lateral mode is a multiple lateral mode having a plurality of (for example, two) substantially elongated elliptical intensity distributions as shown in FIG. 87D.

For example, in a case where the electrical resistance of the first, second, fifth, and sixth regions 105A, 105B, 105E, and 105F decreases, it can be estimated that the lateral mode is a multiple lateral mode having a plurality of relatively small substantially circular intensity distributions (for example, four intensity distributions respectively located at four vertexes of a square) as shown in FIG. 87E.

Although the estimation (detection) of the lateral mode of the emitted light has been described above in Example 1, it is also possible to estimate (detect) a longitudinal mode (spectrum) and a polarization characteristic of the emitted light by measuring the electrical resistance of at least one (preferably at least two) region of the first to sixth regions 105A to 105F.

In addition, by selectively applying a voltage to at least one (preferably at least two) of the first to sixth regions 105A to 105F before driving the surface emitting element, it is possible to inject carriers only to the at least two regions to change the optical characteristic, and it is also possible to adjust the longitudinal mode, the lateral mode, and the polarization characteristic.

(Example 2 of First and Second Electrode Groups)

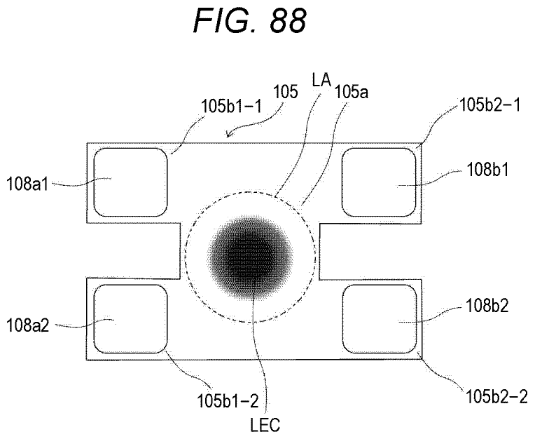

In Example 1, as shown in FIG. 88, the transparent conductive film as the characteristic layer 105 has a plurality of (for example, five) integrated regions (for example, four peripheral regions 105b1-1, 105b1-2, 105b2-1, 105b2-2 and one central region 105a).

In the characteristic layer 105, for example, the four peripheral regions 105b1-1, 105b1-2, 105b2-1, and 105b2-2 are continuous with the central region 105a interposed therebetween. The four peripheral regions 105b1-1, 105b1-2, 105b2-1, and 105b2-2 are located at four corners of a rectangle, for example.

The characteristic layer 105 is disposed such that the central region 105a overlaps the light emitting region LA.

The regions 105b1-1 and 105b2-2 are located on both sides sandwiching the light emitting region LA (for example, on one diagonal line of the rectangle) in plan view. That is, in plan view, a straight line connecting the regions 105b1-1 and 105b2-2 passes through the light emitting region LA.

The regions 105b1-2 and 105b2-1 are located on both sides sandwiching the light emitting region LA (for example, on the other diagonal line of the rectangle) in plan view. That is, in plan view, a straight line connecting the regions 105b1-2 and 105b2-1 passes through the light emitting region LA.

The first electrode 108a1 is provided on the region 105b1-1. The first electrode 108a2 is provided on the region 105b1-2. The second electrode 108b1 is provided on the region 105b2-1. The second electrode 108b2 is provided on the region 105b2-2.

For example, by applying a voltage between the first and second electrodes 108a1 and 108b2, the electrical resistance of a part between the regions 105b1-1 and 105b2-2 of the central region 105a can be measured.

For example, by applying a voltage between the first and second electrodes 108a2 and 108b1, the electrical resistance of a part between the regions 105b1-2 and 105b2-1 of the central region 105a can be measured.

For example, by applying a voltage between the first and second electrodes 108a1 and 108b1, the electrical resistance of a part between the regions 105b1-1 and 105b2-1 of the central region 105a can be measured.

For example, by applying a voltage between the first and second electrodes 108a2 and 108b2, the electrical resistance of a part between the regions 105b1-2 and 105b2-2 of the central region 105a can be measured, and the optical characteristic of the light generated in the light emitting layer can be detected.

For example, by applying a voltage between the two first electrodes 108a1 and 108a2, the electrical resistance of a part between the regions 105b1-1 and 105b1-2 of the central region 105a can be measured.

For example, by applying a voltage between the two second electrodes 108b1 and 108b2, the electrical resistance of a part between the regions 105b2-1 and 105b2-2 of the central region 105a can be measured.

It is therefore possible to estimate (detect) the optical characteristic (for example, the amount, lateral mode, longitudinal mode, polarization characteristic, and the like) of the emitted light by measuring the electrical resistance of the part between any two of the four regions 105b1-1, 105b1-2, 105b2-1, or 105b2-2 in the central region 105a by the above method.

In addition, by selectively applying a voltage to a part between any two of the four regions 105b1-1, 105b1-2, 105b2-1, or 105b2-2 in the central region 105a before driving the surface emitting element, it is possible to inject carriers only to the part and change the optical characteristic, and it is also possible to adjust the optical characteristic (for example, the light amount, lateral mode, longitudinal mode, polarization characteristic, and the like) of the emitted light.

13. Modifications of Present Technology

The present technology is not limited to each of the above-described embodiments and modifications, and various modifications can be made.

In each of the above embodiments and modifications, the surface emitting laser has been described as an example of the surface emitting element of the present technology, but the present technology is also applicable to a light emitting diode (LED). Specifically, the characteristic layer may be disposed so as to overlap a pn junction in a p-type semiconductor layer and an n-type semiconductor layer disposed in contact with each other, and the first and second electrodes or the first and second electrode groups are only required to be provided on the characteristic layer.

An electrical characteristic exhibited by the characteristic layer of the surface emitting element of the present technology may be a photoelectric conversion characteristic. Examples of a material having this photoelectric conversion characteristic include a substrate, a pn junction, a Schottky junction, and a tunnel junction in addition to the transparent conductive film.

In each of the above embodiments and modifications, at least one of the first electrode 108a or the second electrode 108b also serves as an anode electrode that is an electrode for supplying a current to the light emitting layer 103, but may also serve as a cathode electrode that is an electrode for allowing the current supplied to the light emitting layer 103 to flow out. For example, in each of the above embodiments and modifications, at least one of the first electrode 108a or the second electrodes 108b may be a cathode electrode, and the third electrode 109 may be an anode electrode. In this case, it is necessary to appropriately change a conductivity type of a layer constituting the surface emitting element.

For example, in each of the above embodiments and modifications, the first and second electrodes are provided directly on the characteristic layer, but the present disclosure is not limited thereto, and for example, the first and second electrodes may be provided on the characteristic layer with another conductive layer interposed therebetween.

For example, in each of the above embodiments and modifications, the surface emitting element including a GaN-based compound semiconductor has been described. However, instead of this surface emitting element, the present technology can also be applied to a surface emitting element including, for example, an AlGaInN-based compound semiconductor, an AlGaInP-based compound semiconductor, a GaAs compound semiconductor, an AlGaAs-based compound semiconductor, an AlGaInNAs-based compound semiconductor, or the like.

Each of the first and second reflectors 106 and 107 may be a semiconductor multilayer film reflector including a compound of two or more elements of Al, Ga, or As.

For example, in each of the above embodiments and modifications, the front surface emitting type surface emitting element has been described, but the present technology is also applicable to a back surface emitting type surface emitting element that emits light from the back surface of the substrate.

Some of the configurations of the surface emitting elements in each of the embodiments and the modifications described above may be combined in a range not inconsistent with each other.

In each of the embodiments and modifications described above, the material, conductivity type, thickness, width, length, shape, size, arrangement, and the like of each component constituting the surface emitting element can be appropriately changed within a range functioning as the surface emitting element.

14. Application Example to Electronic Device

The technology according to the present disclosure (the present technology) can be applied to various products (electronic devices). For example, the technology according to the present disclosure may be achieved as a device mounted on any type of mobile body such as an automobile, an electric vehicle, a hybrid electric vehicle, a motorcycle, a bicycle, a personal mobility, an airplane, a drone, a boat, a robot, and the like.

The surface emitting element of the present technology can also be applied as, for example, a light source of a device that forms or displays an image by laser light (for example, a laser printer, a laser copier, a projector, a head-mounted display, a head-up display, or the like).

15. <Example in which Surface Emitting Element is Applied to Distance Measuring Device>

Hereinafter, application examples of the surface emitting element according to each of the above embodiments and modifications will be described.

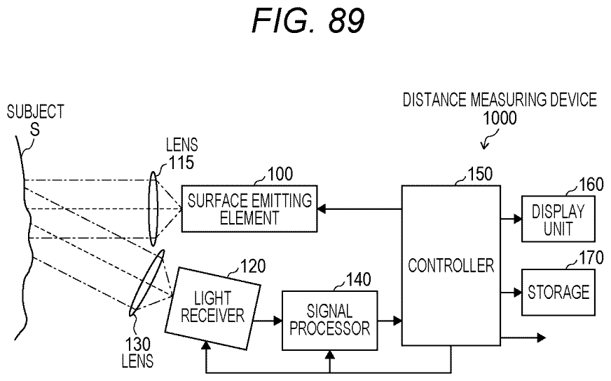

FIG. 89 illustrates an example of a schematic configuration of a distance measuring device 1000 including the surface emitting element 100 as an example of an electronic device of the present technology. The distance measuring device 1000 measures a distance to a subject S by a time of flight (TOF) method. The distance measuring device 1000 includes the surface emitting element 100 as a light source. The distance measuring device 1000 includes, for example, the surface emitting element 100, a light receiver 125, lenses 115 and 135, a signal processor 140, a controller 150, a display unit 160, and a storage 170.

The light receiver 125 detects light reflected by the subject S. The lens 115 is a lens for collimating the light emitted from the surface emitting element 100, and is a collimating lens. The lens 135 is a lens for condensing the light reflected by the subject S and guiding the light to the light receiver 125, and is a condenser lens.

The signal processor 140 is a circuit for generating a signal corresponding to a difference between a signal inputted from the light receiver 125 and a reference signal inputted from the controller 150. The controller 150 includes, for example, a time to digital converter (TDC). The reference signal may be a signal input from the controller 150, or may be an output signal of a detector that directly detects the output of the surface emitting element 100. The controller 150 is, for example, a processor that controls the surface emitting element 100, the light receiver 125, the signal processor 140, the display unit 160, and the storage 170. The controller 150 is a circuit that measures a distance to the subject S on the basis of a signal generated by the signal processor 140. The controller 150 generates a video signal for displaying information regarding a distance to the subject S, and outputs the video signal to the display unit 160. The display unit 160 displays information regarding the distance to the subject S on the basis of the video signal input from the controller 150. The controller 150 stores information regarding the distance to the subject S in the storage 170.

In the present application example, instead of the surface emitting element 100, any of the surface emitting elements 100-1 to 100-3, 200, 200-1, 200-2, 300, 300-1, 400, 500, 500-1, or 500-2 described above can be applied to the distance measuring device 1000.

16. <Example in which Distance Measuring Device is Installed on Mobile Body>

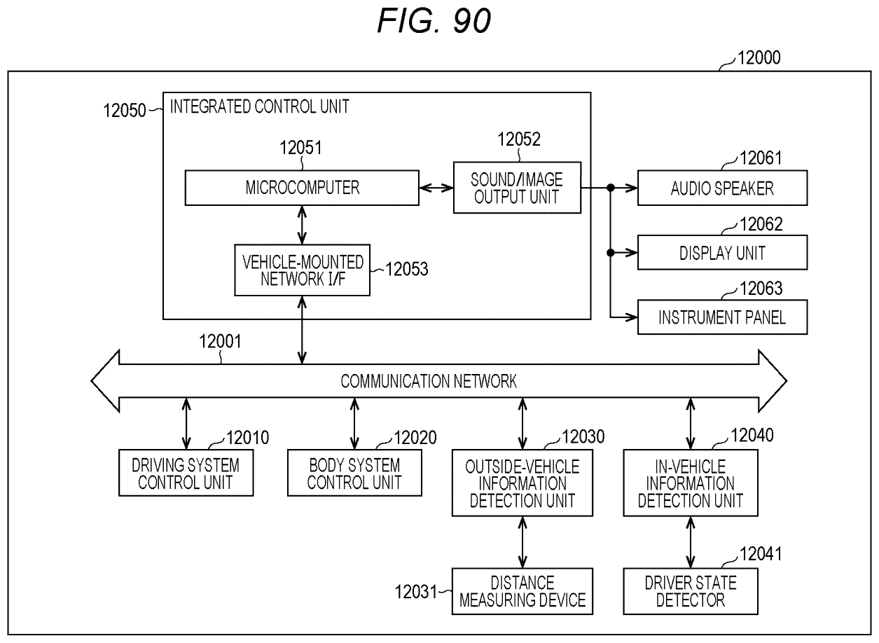

FIG. 90 is a block diagram illustrating an example of a schematic configuration of a vehicle control system as an example of a mobile body control system to which the technology according to the present disclosure can be applied.

The vehicle control system 12000 includes a plurality of electronic control units connected to each other via a communication network 12001. In the example depicted in FIG. 90, the vehicle control system 12000 includes a driving system control unit 12010, a body system control unit 12020, an outside-vehicle information detection unit 12030, an in-vehicle information detection unit 12040, and an integrated control unit 12050. In addition, a microcomputer 12051, a sound/image output unit 12052, and a vehicle-mounted network interface (I/F) 12053 are depicted as a functional configuration of the integrated control unit 12050.

The driving system control unit 12010 controls operation of devices related to a driving system of a vehicle in accordance with various kinds of programs. For example, the driving system control unit 12010 functions as a control device for a driving force generator for generating a driving force of the vehicle, such as an internal combustion engine, a driving motor, or the like, a driving force transmitting mechanism for transmitting the driving force to wheels, a steering mechanism for adjusting a steering angle of the vehicle, a braking device for generating a braking force of the vehicle, and the like.

The body system control unit 12020 controls operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, and the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, and the like of the vehicle.

The outside-vehicle information detection unit 12030 detects information regarding the outside of the vehicle equipped with the vehicle control system 12000. For example, a distance measuring device 12031 is connected to the outside-vehicle information detection unit 12030. The distance measuring device 12031 includes the above-described distance measuring device 1000. The outside-vehicle information detection unit 12030 causes the distance measuring device 12031 to measure a distance to an object (the subject S) outside the vehicle, and acquires distance data obtained by the measurement. The outside-vehicle information detection unit 12030 may perform object detection processing of a person, a vehicle, an obstacle, a sign, or the like on the basis of the acquired distance data.

The in-vehicle information detection unit 12040 detects information regarding the inside of the vehicle. For example, a driver state detector 12041 that detects a state of a driver is connected to the in-vehicle information detection unit 12040. The driver state detector 12041, for example, includes a camera that images the driver. On the basis of detection information input from the driver state detector 12041, the in-vehicle information detection unit 12040 may calculate a degree of fatigue of the driver or a degree of concentration of the driver, or may determine whether or not the driver is dozing.

The microcomputer 12051 can calculate a control target value for the driving force generator, the steering mechanism, or the braking device on the basis of the information regarding the inside or outside of the vehicle, the information being obtained by the outside-vehicle information detection unit 12030 or the in-vehicle information detection unit 12040, and output a control command to the driving system control unit 12010. For example, the microcomputer 12051 can perform cooperative control intended to implement functions of an advanced driver assistance system (ADAS), the functions including collision avoidance or shock mitigation for the vehicle, follow-up traveling based on an inter-vehicle distance, vehicle speed maintaining traveling, vehicle collision warning, vehicle lane departure warning, and the like.

In addition, the microcomputer 12051 can perform cooperative control intended for automated driving, which makes the vehicle to travel automatedly without depending on the operation of the driver, or the like, by controlling the driving force generator, the steering mechanism, the braking device, or the like on the basis of the information regarding the outside or inside of the vehicle, the information being obtained by the outside-vehicle information detection unit 12030 or the in-vehicle information detection unit 12040.

Furthermore, the microcomputer 12051 can output a control command to the body system control unit 12020 on the basis of information regarding the outside of the vehicle, the information being acquired by the outside-vehicle information detection unit 12030. For example, the microcomputer 12051 can perform cooperative control intended to prevent a glare, for example, by controlling the headlamp so as to switch from a high beam to a low beam, for example, in accordance with the position of a preceding vehicle or an oncoming vehicle detected by the outside-vehicle information detection unit 12030.

The sound/image output unit 12052 transmits an output signal of at least one of a sound or an image to an output device capable of visually or auditorily notifying an occupant of the vehicle or the outside of the vehicle of information. In the example of FIG. 90, an audio speaker 12061, a display unit 12062, and an instrument panel 12063 are illustrated as the output device. The display unit 12062 may, for example, include at least one of an on-board display or a head-up display.

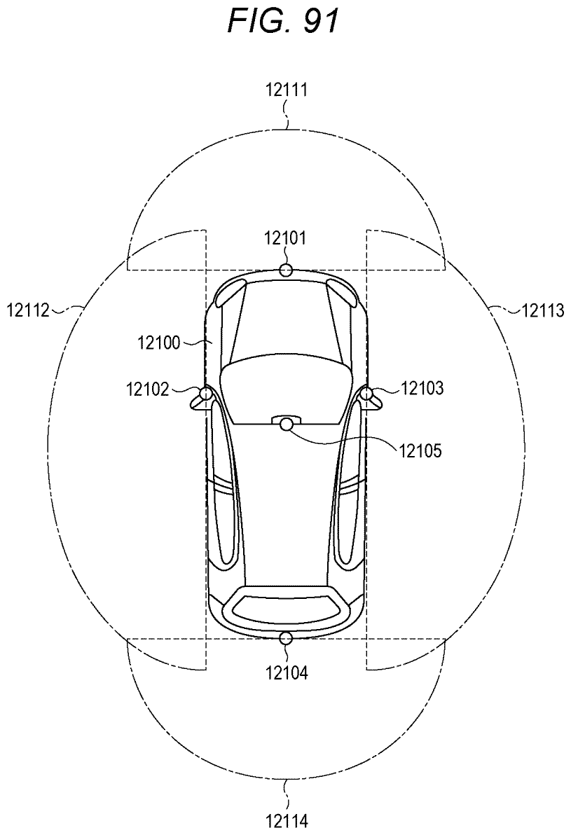

FIG. 91 is a view illustrating an example of an installation position of the distance measuring device 12031.

In FIG. 91, a vehicle 12100 includes distance measuring devices 12101, 12102, 12103, 12104, and 12105 as the distance measuring device 12031.

The distance measuring devices 12101, 12102, 12103, 12104, and 12105 are provided at positions such as, for example, a front nose, side mirrors, a rear bumper, a back door, and an upper part of a windshield in a vehicle cabin, of the vehicle 12100. The distance measuring device 12101 provided at the front nose and the distance measuring device 12105 provided at the upper part of the windshield in the vehicle cabin mainly acquire data of a front side of the vehicle 12100. The distance measuring devices 12102 and 12103 provided at the side mirrors mainly acquire data of a side of the vehicle 12100. The distance measuring device 12104 provided at the rear bumper or the back door mainly acquires data of a rear side of the vehicle 12100. The data of the front side acquired by the distance measuring devices 12101 and 12105 is mainly used for detecting a preceding vehicle, a pedestrian, an obstacle, a traffic light, a traffic sign, or the like.

Note that FIG. 91 illustrates an example of detection ranges of the distance measuring devices 12101 to 12104. A detection range 12111 indicates a detection range of the distance measuring device 12101 provided at the front nose, detection ranges 12112 and 12113 individually indicate detection ranges of the distance measuring devices 12102 and 12103 provided at the side mirrors, and a detection range 12114 indicates a detection range of the distance measuring device 12104 provided at the rear bumper or the back door.

For example, the microcomputer 12051 can determine a distance to each three-dimensional object within the detection ranges 12111 to 12114 and a temporal change in the distance (a relative speed with respect to the vehicle 12100) on the basis of the distance data obtained from the distance measuring devices 12101 to 12104, and thereby extract, as a preceding vehicle, a nearest three-dimensional object in particular that is present on a traveling path of the vehicle 12100 and travels in substantially the same direction as the vehicle 12100 at a predetermined speed (for example, equal to or more than 0 km/hour). Moreover, the microcomputer 12051 can set an inter-vehicle interval to be secured from a preceding vehicle in advance, and perform automatic brake control (including follow-up stop control), automatic acceleration control (including follow-up start control), and the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance data obtained from the distance measuring devices 12101 to 12104, extract the classified three-dimensional object data, and use the extracted three-dimensional object data for automatic avoidance of an obstacle. For example, the microcomputer 12051 distinguishes obstacles around the vehicle 12100 into obstacles that are visible to the driver of the vehicle 12100 and obstacles that are difficult to see. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display unit 12062, and performs forced deceleration or avoidance steering via the driving system control unit 12010. The microcomputer 12051 can thereby assist in driving to avoid collision.

An example of the mobile body control system to which the technology according to the present disclosure can be applied has been described above. The technology according to the present disclosure can be applied to the distance measuring device 12031 among the configurations described above.

Furthermore, the present technology can also have the following configurations.
(1) A surface emitting element includes
a light emitting layer,
a characteristic layer that is disposed on an optical path of light generated in the light emitting layer, exhibits an electrical characteristic due to light incidence, and/or has variability in an optical characteristic due to voltage application, and
a plurality of electrodes provided on the characteristic layer.
(2) In the surface emitting element according to (1), the light emitting layer and the characteristic layer are stacked on each other.
(3) In the surface emitting element according to (1) or (2), the plurality of electrodes is disposed apart from each other along the characteristic layer.
(4) The surface emitting element according to any one of (1) to (3) further includes a first reflector and a second reflector disposed at positions sandwiching the light emitting layer, in which the characteristic layer is disposed between one of the first reflector or the second reflector and the light emitting layer.
(5) In the surface emitting element according to any one of (1) to (4), the electrical characteristic includes a characteristic in which an electrical resistance changes in accordance with a change in an amount of incident light.
(6) In the surface emitting element according to any one of (1) to (5), the variability in the optical characteristic includes that a light absorption end is shifted to a short wavelength side or a long wavelength side by the voltage application.
(7) In the surface emitting element according to any one of (1) to (6), the characteristic layer absorbs a part of the incident light.
(8) In the surface emitting element according to any one of (1) to (7), the characteristic layer includes a transparent conductive film.
(9) In the surface emitting element according to any one of (1) to (8), the electrical characteristic includes a photoelectric conversion characteristic.
(10) In the surface emitting element according to any one of (1) to (9), the light emitting layer has a light emitting region and a non-light emitting region that surrounds the light emitting region, and the plurality of electrodes includes at least one first electrode disposed at a position corresponding to a section on one side of both sides sandwiching the light emitting region in the non-light emitting region, the plurality of electrodes including at least one second electrode disposed at a position corresponding to a section on an another side of the both sides.
(11) In the surface emitting element according to (10), the characteristic layer is disposed so as to overlap at least a position having a highest light emission intensity in an in-plane direction of the light emitting region.
(12) In the surface emitting element according to (10) or (11), in the characteristic layer, a size of a region corresponding to the light emitting region is smaller in plan view than a size of a region corresponding to the non-light emitting region on each of the both sides sandwiching the light emitting region.
(13) In the surface emitting element according to any one of (10) to (12), in the region corresponding to the light emitting region of the characteristic layer, a part corresponding to the position having the highest light emission intensity has a smallest size in plan view.
(14) In the surface emitting element according to any one of (10) to (13), the at least one first electrode includes a first electrode group including a plurality of first electrodes, the at least one second electrode includes a second electrode group including a plurality of second electrodes corresponding to the plurality of the first electrodes, and a plurality of electrode pairs each including the plurality of first electrode electrodes and the plurality of second electrodes corresponding to each other is disposed at positions corresponding to a plurality of different regions in the in-plane direction of the characteristic layer.
(15) In the surface emitting element according to (14), the plurality of regions is integrated.
(16) In the surface emitting element according to claim 14), at least two of the plurality of regions are separated from each other.
(17) In the surface emitting element according to any one of (1) to (16), at least one of the plurality of electrodes also serves as an electrode for supplying a current to the light emitting layer or an electrode for flowing out the current supplied to the light emitting layer.
(18) A method for detecting an optical characteristic of a light emitted from a surface emitting element including a light emitting layer, a characteristic layer that is disposed on an optical path of light generated in the light emitting layer and exhibits an electrical characteristic due to light incidence, and a plurality of electrodes including a first electrode and a second electrode provided on the characteristic layer includes
applying substantially the same potential to the first electrode and the second electrode to drive the surface emitting element,
generating a potential difference between the first electrode and the second electrode by superimposing a potential on at least one of the first electrode or the second electrode while the surface emitting element is being driven, and
measuring the electrical characteristic of the characteristic layer.
(19) A method for detecting an optical characteristic of a light emitted from a surface emitting element including a light emitting layer, a characteristic layer that is disposed on an optical path of light generated in the light emitting layer and exhibits an electrical characteristic due to light incidence, a plurality of electrodes including a first electrode and a second electrode provided on the characteristic layer, and a third electrode disposed on a side opposite to the characteristic layer of the light emitting layer includes
applying substantially the same potential to the first electrode and the second electrode to drive the surface emitting element,
turning off driving of the surface emitting element and applying substantially the same potential to one of the first electrode or the second electrode and the third electrode, and
measuring the electrical characteristic of the characteristic layer.
(20) A method for adjusting an optical characteristic of a light emitted from a surface emitting element including a light emitting layer, a characteristic layer that is disposed on an optical path of light generated in the light emitting layer and has variability in an optical characteristic due to voltage application, a plurality of electrodes including a first electrode and a second electrode provided on the characteristic layer, and a third electrode disposed on a side opposite to the characteristic layer of the light emitting layer includes
applying a potential to one of the first electrode or the second electrode to generate a potential difference between the first electrode and the second electrode, and applying a potential substantially the same as the potential to the third electrode to inject carriers into the characteristic layer, and
driving the surface emitting element by generating a potential difference between at least one of the first electrode or the second electrode and the third electrode.

### REFERENCE SIGNS LIST

100, 100-1 to 100-3, 200, 200-1, 200-2, 300, 300-1, 400, 500, 500-1, 500-2 Surface emitting element
101 Substrate
102 Second cladding layer
103 Active layer
104 First cladding layer
105 Characteristic layer
106 First reflector
107 Second reflector
108a First electrode
108b Second electrode
109 Third electrode
LA Light emitting region
NLA Non-light emitting region
NLA1 Section on one side of non-light emitting region
NLA2 Non-light emitting region on another side of non-light emitting region
LEC Position having highest light emission intensity

1. A surface emitting element comprising:
a light emitting layer;
a characteristic layer that is disposed on an optical path of light generated in the light emitting layer, exhibits an electrical characteristic due to light incidence, and/or has variability in an optical characteristic due to voltage application; and
a plurality of electrodes provided on the characteristic layer.

2. The surface emitting element according to claim 1, wherein the light emitting layer and the characteristic layer are stacked on each other.

3. The surface emitting element according to claim 1, wherein the plurality of electrodes is disposed apart from each other along the characteristic layer.

4. The surface emitting element according to claim 1, further comprising
a first reflector and a second reflector disposed at positions sandwiching the light emitting layer, wherein
the characteristic layer is disposed between one of the first reflector or the second reflector and the light emitting layer.

5. The surface emitting element according to claim 1, wherein the electrical characteristic includes a characteristic in which an electrical resistance changes in accordance with a change in an amount of incident light.

6. The surface emitting element according to claim 1, wherein the variability in the optical characteristic includes that a light absorption end is shifted to a short wavelength side or a long wavelength side by the voltage application.

7. The surface emitting element according to claim 1, wherein the characteristic layer absorbs a part of the incident light.

8. The surface emitting element according to claim 1, wherein the characteristic layer includes a transparent conductive film.

9. The surface emitting element according to claim 1, wherein the electrical characteristic includes a photoelectric conversion characteristic.

10. The surface emitting element according to claim 1, wherein
the light emitting layer has a light emitting region and a non-light emitting region that surrounds the light emitting region, and
the plurality of electrodes includes at least one first electrode disposed at a position corresponding to a section on one side of both sides sandwiching the light emitting region in the non-light emitting region, the plurality of electrodes including at least one second electrode disposed at a position corresponding to a section on an another side of the both sides.

11. The surface emitting element according to claim 10, wherein the characteristic layer is disposed so as to overlap at least a position having a highest light emission intensity in an in-plane direction of the light emitting region.

12. The surface emitting element according to claim 10, wherein, in the characteristic layer, a size of a region corresponding to the light emitting region is smaller in plan view than a size of a region corresponding to the non-light emitting region on each of the both sides sandwiching the light emitting region.

13. The surface emitting element according to claim 12, wherein, in the region corresponding to the light emitting region of the characteristic layer, a part corresponding to the position having the highest light emission intensity has a smallest size in plan view.

14. The surface emitting element according to claim 10, wherein
the at least one first electrode includes a first electrode group including a plurality of first electrodes,
the at least one second electrode includes a second electrode group including a plurality of second electrodes corresponding to the plurality of the first electrodes, and
a plurality of electrode pairs each including the plurality of first electrode electrodes and the plurality of second electrodes corresponding to each other is disposed at positions corresponding to a plurality of different regions in the in-plane direction of the characteristic layer.

15. The surface emitting element according to claim 14, wherein the plurality of regions is integrated.

16. The surface emitting element according to claim 14, wherein at least two of the plurality of regions are separated from each other.

17. The surface emitting element according to claim 1, wherein at least one of the plurality of electrodes also serves as an electrode for supplying a current to the light emitting layer or an electrode for flowing out the current supplied to the light emitting layer.

18. A method for detecting an optical characteristic of a light emitted from a surface emitting element including a light emitting layer, a characteristic layer that is disposed on an optical path of light generated in the light emitting layer and exhibits an electrical characteristic due to light incidence, and a plurality of electrodes including a first electrode and a second electrode provided on the characteristic layer, the method comprising:
applying substantially a same potential to the first electrode and the second electrode to drive the surface emitting element;
generating a potential difference between the first electrode and the second electrode by superimposing a potential on at least one of the first electrode or the second electrode while the surface emitting element is being driven; and
measuring the electrical characteristic of the characteristic layer.

19. A method for detecting an optical characteristic of a light emitted from a surface emitting element including a light emitting layer, a characteristic layer that is disposed on an optical path of light generated in the light emitting layer and exhibits an electrical characteristic due to light incidence, a plurality of electrodes including a first electrode and a second electrode provided on the characteristic layer, and a third electrode disposed on a side opposite to the characteristic layer of the light emitting layer, the method comprising:
applying substantially a same potential to the first electrode and the second electrode to drive the surface emitting element;
turning off driving of the surface emitting element and applying substantially a same potential to one of the first electrode or the second electrode and the third electrode; and
measuring the electrical characteristic of the characteristic layer.

20. A method for adjusting an optical characteristic of a light emitted from a surface emitting element including a light emitting layer, a characteristic layer that is disposed on an optical path of light generated in the light emitting layer and has variability in an optical characteristic due to voltage application, a plurality of electrodes including a first electrode and a second electrode provided on the characteristic layer, and a third electrode disposed on a side opposite to the characteristic layer of the light emitting layer, the method comprising:
applying a potential to one of the first electrode or the second electrode to generate a potential difference between the first electrode and the second electrode, and applying a potential substantially same as the potential to the third electrode to inject carriers into the characteristic layer; and
driving the surface emitting element by generating a potential difference between at least one of the first electrode or the second electrode and the third electrode.
